(19) United States
(12) Patent Application Publication
(10) Pub. No.: US 2026/0130082 A1
(43) Pub. Date: May 7, 2026

(54) DISPLAY PANEL AND DISPLAY DEVICE

(71) Applicants: Hefei BOE Joint Technology Co., Ltd., Hefei, Anhui (CN); BOE Technology Group Co., Ltd., Beijing (CN)

(72) Inventors: Can YUAN, Beijing (CN); Yongqian LI, Beijing (CN); Biao TIAN, Beijing (CN)

(73) Assignees: Hefei BOE Joint Technology Co., Ltd., Hefei, Anhui (CN); BOE Technology Group Co., Ltd., Beijing (CN)

(21) Appl. No.: 18/996,162

(22) PCT Filed: May 28, 2024
(86) PCT No.: PCT/CN2024/095856

§ 371 Date: Jan. 17, 2025

(30) Foreign Application Priority Data
Apr. 17, 2024 (CN) 202410465765.6

(51) Int. Cl. H10K 59/131; H10K 59/35

(52) U.S. Cl. CPC H10K 59/1315; H10K 59/351

(57) ABSTRACT

Provided is a display panel. The display panel includes a base substrate, a plurality of pixel units, and a plurality of gate signal lines. The base substrate has a display region and a periphery region surrounding the display region, wherein the display region includes a plurality of pixel light-emitting regions and a plurality of transparent regions, the plurality of transparent regions including at least one target transparent region arranged in a first direction. The plurality of pixel units, disposed on the base substrate and in the plurality of pixel light-emitting regions. The plurality of gate signal lines are arranged in a second direction.

### CROSS-REFERENCE TO RELATED APPLICATION

This application is a U.S. national stage of international application No. PCT/CN 2024/095856, filed on May 28, 2024, which claims priority to Chinese Patent Application No. 202410465765.6, filed on Apr. 17, 2024 and entitled “DISPLAY PANEL AND DISPLAY DEVICE,” the disclosure of each is herein incorporated by reference in its entirety.

### TECHNICAL FIELD

The present disclosure relates to the technical field of display, and in particular, relates to a display panel and a display device.

### BACKGROUND

A display penal generally includes a plurality of pixel units arranged in an array in a display region of a base substrate, and gate signal lines (generally referred to as Gate traces) configured to supply gate drive signals to the plurality of pixel units.

### SUMMARY

A display panel and a display device are provided in the present disclosure. The technical solutions are as follows.

In some embodiments of the present disclosure, a display panel is provided. The display panel includes:
a base substrate, having a display region and a periphery region surrounding the display region, wherein the display region includes a plurality of pixel light-emitting regions and a plurality of transparent regions, the plurality of transparent regions including at least one target transparent region arranged in a first direction;
a plurality of pixel units, disposed on the base substrate and in the plurality of pixel light-emitting regions; and
a plurality of gate signal lines, arranged in a second direction, wherein the second direction is intersected with the first direction, and each of the plurality of gate signal lines includes a first section in the periphery region and a second section in the display region, wherein the second section includes a body portion extending in the first direction and a bent portion connected to the body portion, the bent portion being disposed in the at least one target transparent region, and a path length of the bent portion being greater than a length of the at least one target transparent region in the first direction.

In some embodiments, the display panel further includes: a protection pattern and a first insulation layer between the protection pattern and the plurality of gate signal lines,
wherein the protection pattern is disposed in the at least one target transparent region, an orthographic projection of the bent portion on the base substrate is on a side of an orthographic projection of the protection pattern on the base substrate, and the orthographic projection of the protection pattern on the base substrate is partially overlapped with the orthographic projection of the bent portion on the base substrate.

In some embodiments, the bent portion includes a first bent portion, a second bent portion, and a third bent portion that are connected in sequence, and the plurality of gate signal lines form a plurality of signal line groups, each group of the plurality of signal line groups including two adjacent gate signal lines; wherein
the first bent portion in each of the two adjacent gate signal lines is disposed in a side, away from the periphery region, of the protection pattern, and the third bent portion in each of the two adjacent gate signal lines is disposed in a side, close to the periphery region, of the protection pattern; and
an orthographic projection of the second bent portion of a first gate signal line in the two adjacent gate signal lines on the base substrate is on a first side of the orthographic projection of the protection pattern on the base substrate and is partially overlapped with the orthographic projection of the protection pattern on the base substrate, and an orthographic projection of the second bent portion of a second gate signal line in the two adjacent gate signal lines on the base substrate is on a second side of the orthographic projection of the protection pattern on the base substrate and is partially overlapped with the orthographic projection of the protection pattern on the base substrate, wherein the first side and the second side are two sides, arranged in the second direction, of the orthographic projection of the protection pattern on the base substrate.

In some embodiments, orthographic projections of bent portions of the two gate signal lines on the base substrate surround the orthographic projection of the protection pattern on the base substrate.

In some embodiments, the bent portions of the two gate signal lines define a first annular region,
a portion of the first gate signal line in one of the plurality of pixel light-emitting regions has a second annular region, and a portion of the second gate signal line in one of the plurality of pixel light-emitting regions has a third annular region;
wherein an area of the first annular region is greater than an area of the second annular region and an area of the third annular region.

In some embodiments, the at least one target transparent region include a first target transparent region, wherein the first target transparent region is closer to the periphery region than the plurality of pixel light-emitting regions;
wherein for the first annular region defined by the bent portions of the two gate signal lines in the first target transparent region, a distance between the first annular region and one of the plurality of pixel light-emitting regions is greater than a distance between the first annular region and the periphery region.

In some embodiments, the protection pattern is a stripe pattern extending in the second direction, and a length of the protection pattern in the second direction is greater than the distance between the first annular region in the first target transparent region and one of the plurality of pixel light-emitting regions.

In some embodiments, the at least one target transparent region further includes a second target transparent region, wherein the second target transparent region is disposed between two adjacent pixel light-emitting regions in the plurality of pixel light-emitting regions;
wherein for the first annular region defined by the bent portions of the two gate signal lines in the second target transparent region, distances between the second annular region and the two adjacent pixel light-emitting regions are equal.

In some embodiments, a first protrusion is arranged on a side, close to the protection pattern, of the second bent portion of the first gate signal line, wherein an orthographic projection of a first end portion of the protection pattern on the base substrate is overlapped with an orthographic projection of the first protrusion on the base substrate; and
a second protrusion is arranged on a side, close to the protection pattern, of the second bent portion of the second gate signal line, wherein an orthographic projection of a second end portion of the protection pattern on the base substrate is overlapped with an orthographic projection of the second protrusion on the base substrate.

In some embodiments, the display includes: a pixel unit layer, wherein the pixel unit layer includes the plurality of pixel units and a semiconductor layer between the base substrate and the first insulation layer,
wherein the protection pattern is disposed in the semiconductor layer, and each of the first end portion and the second end portion of the protection pattern is made of a semiconductor material.

In some embodiments, the display includes: a pixel unit layer, wherein the pixel unit layer includes the plurality of pixel units, and a gate layer, a second insulation layer, and a cathode layer that are stacked in a direction away from the base substrate in sequence;
wherein the plurality of gate signal lines are disposed in the gate layer, an orthographic projection of the second insulation layer on the base substrate covers orthographic projections of the plurality of gate signal lines on the base substrate and the orthographic projection of the protection pattern on the base substrate.

In some embodiments, the second insulation layer includes a material region containing an insulative material and a void region without any insulative material; wherein
the material region is disposed in the plurality of pixel light-emitting regions, and an orthographic projection of the material region on the base substrate covers the orthographic projection of the protection pattern on the base substrate and the orthographic projections of the plurality of gate signal lines on the base substrate; and
the void region is disposed on a side, away from the orthographic projection of the protection pattern on the base substrate, of the orthographic projections of the plurality of gate signal lines on the base substrate, disposed between the orthographic projections of the plurality of gate signal lines on the base substrate and the orthographic projection of the protection pattern on the base substrate, and disposed in other regions of the plurality of transparent regions than regions of the orthographic projections of the plurality of gate signal lines on the base substrate.

In some embodiments, the second insulation layer at least includes a first insulation sub-layer and a second insulation sub-layer that are stacked in the direction away from the base substrate in sequence,
wherein a boundary of an orthographic projection of the first insulation sub-layer on the base substrate is not overlapped with a boundary of an orthographic projection of the second insulation sub-layer on the base substrate.

In some embodiments, each of the plurality of pixel light-emitting regions and the plurality of transparent regions is a stripe region extending in the second direction, the plurality of pixel light-emitting regions and the plurality of transparent regions are staggered in the first direction, the plurality of transparent regions include two target transparent regions, and the plurality of pixel light-emitting regions and other transparent regions in the plurality of transparent regions than the two target transparent regions are disposed between the two target transparent regions; and
each of the plurality of gate signal lines includes two bent portions, wherein one bent portion in the two bent portions is connected to an end of the body portion and is disposed in one target transparent region in the two target transparent regions, and another bent portion in the two bent portions is connected to another end of the body portion and is disposed in another target transparent region in the two target transparent regions.

In some embodiments, the plurality of pixel units are arranged in an array and include a plurality of first pixel unit groups arranged in the second direction, wherein each group of the plurality of first pixel unit groups includes multiple pixel units arranged in the first direction, each of the plurality of gate signal lines is connected to the multiple pixel units in one group of the plurality of first pixel unit groups, and the multiple pixel units in the each group of the plurality of first pixel unit groups are connected to two gate signal lines in one group of a plurality of signal line groups formed by the plurality of gate signal lines.

In some embodiments, each of the plurality of pixel units include a first group of sub-pixels and a second group of sub-pixels that are arranged in the second direction, wherein the first group of sub-pixels includes at least one sub-pixel, the second group of sub-pixels includes at least one sub-pixel, and
body portions of the two gate signal lines connected to the multiple pixel units in the each group of the plurality of first pixel unit groups are disposed between the first group of sub-pixels and the second group of sub-pixels.

In some embodiments, the body portion includes a first primary path line and a plurality of first secondary path lines; wherein
two ends of each of the plurality of first secondary path lines are connected to the first primary path line, the first primary path line is connected to the at least one sub-pixel in first groups of sub-pixels of the multiple pixel units in one group of the plurality of first pixel unit groups, and each of the plurality of first secondary path lines is connected to the at least one sub-pixel in the second group of sub-pixels of one of the multiple pixel units.

In some embodiments, the plurality of pixel units include a plurality of second pixel unit groups arranged in the first direction, wherein each group of the plurality of second pixel unit groups includes multiple pixel units arranged in the second direction;
the display panel further includes a plurality of first power lines corresponding to the plurality of second pixel unit groups, and a plurality of corresponding auxiliary electrode lines, wherein each of the plurality of first power lines includes a primary power line and a plurality of branch power lines, the plurality of branch power lines being connected to the primary power line, and the primary power line being disposed on a side of a corresponding second pixel unit group; each of the plurality of first power lines is connected to sub-pixels in the multiple pixel units in one group of the plurality of second pixel unit groups, and each of the plurality of auxiliary electrode lines is disposed on another side of the corresponding second pixel unit group and is connected to a cathode layer in the multiple pixel units; and
for the primary power line and one of the plurality of auxiliary electrode lines of one of the plurality of first power lines corresponding to one group of the plurality of second pixel unit groups, one of connection positions between the two ends of one of the plurality of first secondary path lines and the first primary path line is disposed on a side, away from the one of the plurality of auxiliary electrode lines, of the primary power line, and another of the connection positions between the two ends of one of the plurality of first secondary path lines and the first primary path line is disposed on a side, away from the primary power line, of the one of the plurality of auxiliary electrode lines.

In some embodiments, the plurality of pixel units include a plurality of second pixel unit groups arranged in the first direction, wherein each group of the plurality of second pixel unit groups includes multiple pixel units arranged in the second direction;
the display panel further includes a plurality of first power lines corresponding to the plurality of second pixel unit groups, and a plurality of corresponding auxiliary electrode lines, wherein each of the plurality of first power lines includes a primary power line and a plurality of branch power lines, the plurality of branch power lines being connected to the primary power line, and the primary power line being disposed on a side of a corresponding second pixel unit group; each of the plurality of first power lines is connected to the multiple pixel units in one group of the plurality of second pixel unit groups, and each of the plurality of auxiliary electrode lines is disposed on another side of the corresponding second pixel unit group and is connected to a cathode layer in the multiple pixel units;
for the primary power line and one of the plurality of auxiliary electrode lines of one of the plurality of first power lines corresponding to one group of the plurality of second pixel unit groups, two connection positions between the two ends of one of the plurality of first secondary path lines and the first primary path line are disposed between the primary power line and the one of the plurality of auxiliary electrode lines; and
the body portion further includes a plurality of second secondary path lines and a plurality of third secondary path lines, wherein two ends of each of the plurality of second secondary path lines are connected to the first primary path line, and two connection positions between the two ends of each of the plurality of second secondary path lines and the first primary path line are disposed on two side of the primary power line; and two ends of each of the plurality of third secondary path lines are connected to the first primary path line, and two connection positions between the two ends of each of the plurality of third secondary path lines and the first primary path line are disposed on two side of the one of the plurality of auxiliary electrode lines.

In some embodiments, the first group of sub-pixels includes a first sub-pixel and a second sub-pixel, and the second group of sub-pixels includes a third sub-pixel and a fourth sub-pixel; and the display panel further includes a plurality of data signal line groups corresponding to the plurality of second pixel unit groups, wherein each group of the plurality of data signal line groups includes a plurality of data signal lines arranged in the first direction, a target data signal line in the plurality of data signal lines being disposed between the first sub-pixel and the second sub-pixel and between the third sub-pixel and the fourth sub-pixel, and being at least one data signal line in the plurality of data signal lines; and
each of the plurality of branch power lines includes a second primary path line and a fourth secondary path line, wherein two ends of the fourth secondary path line are connected to the second primary path line, and two connection positions between the two ends of the fourth secondary path line and the second primary path line are disposed on two sides of the target data signal line.

In some embodiments of the present disclosure, a display device is provided. The display device includes: a power supply assembly, and the display panel according to above embodiments;

wherein the power supply assembly is connected to the display panel and is configured to supply power to the display panel.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display panel according to some embodiments of the present disclosure;

FIG. 2 is a partial schematic structural diagram of the display panel shown in FIG. 1;

FIG. 3 is a partial schematic structural diagram of a display panel according to some embodiments of the present disclosure;

FIG. 4 is a partial schematic structural diagram of a display panel according to some embodiments of the present disclosure;

FIG. 5 is a schematic diagram of a protection pattern and bent portions of gate signal lines according to some embodiments of the present disclosure;

FIG. 6 is a partial schematic diagram of a display panel according to some embodiments of the present disclosure;

FIG. 7 is a partial schematic diagram of a first insulation sub-layer according to some embodiments of the present disclosure;

FIG. 8 is a partial schematic diagram of a second insulation sub-layer according to some embodiments of the present disclosure;

FIG. 9 is a partial schematic diagram of stack of a first insulation sub-layer and a second insulation sub-layer according to some embodiments of the present disclosure;

FIG. 10 is a schematic diagram of a pixel unit according to some embodiments of the present disclosure;

FIG. 11 is an equivalent circuit diagram of a pixel circuit of a sub-pixel according to some embodiments of the present disclosure;

FIG. 12 is a local section view of a display panel according to some embodiments of the present disclosure;

FIG. 13 is a partial schematic diagram of a light-shielding layer according to some embodiments of the present disclosure;

FIG. 14 is a partial schematic diagram of a semiconductor layer according to some embodiments of the present disclosure;

FIG. 15 is a partial schematic diagram of stack of a light-shielding layer and a semiconductor layer according to some embodiments of the present disclosure;

FIG. 16 is a partial schematic diagram of a gate layer in a display panel according to some embodiments of the present disclosure;

FIG. 17 is a partial schematic diagram of stack of a light-shielding layer, a semiconductor layer, and a gate layer according to some embodiments of the present disclosure;

FIG. 18 is a partial schematic diagram of an interlayer dielectric layer according to some embodiments of the present disclosure;

FIG. 19 is a partial schematic diagram of an interlayer dielectric layer according to some embodiments of the present disclosure;

FIG. 20 is a partial schematic diagram of stack of a light-shielding layer, a semiconductor layer, a gate layer, and an interlayer dielectric layer according to some embodiments of the present disclosure;

FIG. 21 is a partial schematic diagram of a source and drain layer according to some embodiments of the present disclosure;

FIG. 22 is a partial schematic diagram of stack of a light-shielding layer, a semiconductor layer, a gate layer, an interlayer dielectric layer, and a source and drain layer according to some embodiments of the present disclosure;

FIG. 23 is a partial schematic diagram of a planarization layer according to some embodiments of the present disclosure;

FIG. 24 is a partial schematic diagram of stack of a light-shielding layer, a semiconductor layer, a gate layer, an interlayer dielectric layer, a source and drain layer, and a planarization layer according to some embodiments of the present disclosure;

FIG. 25 is a partial schematic diagram of a passivation layer according to some embodiments of the present disclosure;

FIG. 26 is a partial schematic diagram of stack of a light-shielding layer, a semiconductor layer, a gate layer, an interlayer dielectric layer, a source and drain layer, a passivation layer, and a planarization layer according to some embodiments of the present disclosure;

FIG. 27 is a partial schematic diagram of a first anode film layer in an anode layer according to some embodiments of the present disclosure;

FIG. 28 is a partial schematic diagram of stack of a light-shielding layer, a semiconductor layer, a gate layer, an interlayer dielectric layer, a source and drain layer, a passivation layer, a planarization layer, and a first anode film layer according to some embodiments of the present disclosure;

FIG. 29 is a partial schematic diagram of a second anode film layer in an anode layer according to some embodiments of the present disclosure;

FIG. 30 is a partial schematic diagram of stack of a light-shielding layer, a semiconductor layer, a gate layer, an interlayer dielectric layer, a source and drain layer, a passivation layer, a planarization layer, a first anode film layer, and a second anode film layer according to some embodiments of the present disclosure;

FIG. 31 is a partial schematic diagram of a third anode film layer in an anode layer according to some embodiments of the present disclosure;

FIG. 32 is a partial schematic diagram of stack of a light-shielding layer, a semiconductor layer, a gate layer, an interlayer dielectric layer, a source and drain layer, a passivation layer, a planarization layer, a first anode film layer, a second anode film layer, and a third anode film layer according to some embodiments of the present disclosure;

FIG. 33 is a partial schematic diagram of a pixel define layer according to some embodiments of the present disclosure;

FIG. 34 is a partial schematic diagram of stack of a light-shielding layer, a semiconductor layer, a gate layer, an interlayer dielectric layer, a source and drain layer, a passivation layer, a planarization layer, a first anode film layer, a second anode film layer, a third anode film layer, and a pixel define layer according to some embodiments of the present disclosure;

FIG. 35 is a schematic diagram of an intrusion path of moisture or oxygen according to some embodiments of the present disclosure; and

FIG. 36 is a schematic structural diagram of a display device according to some embodiments of the present disclosure.

### DETAILED DESCRIPTION

For clearer descriptions of the objects, technical solutions, and advantages of the present disclosure, the embodiments of the present disclosure are described in detail hereinafter in combination with the accompanying drawings.

In some practices, a base substrate includes a display region and a periphery region surrounding the display region. Two ends of a gate signal line are disposed in the periphery region to connect gate drive circuits, and a middle portion of the gate signal line is disposed in the display region to connect pixel units. In general, an organic layer is disposed between the gate signal line and a cathode layer to avoid a large parasitic capacitance due to a less distance between the gate signal line and the cathode layer of the pixel unit in a vertical direction. The organic layer may increase the distance between the gate signal line and the cathode layer of the pixel unit in the vertical direction due to a thickness of the organic layer. The vertical direction is perpendicular to a bearing face of the base substrate.

However, the organic layer is generally made of a hydrophilic material, the organic layer is in contact with two ends of the gate signal line in the periphery region, and the organic layer is also disposed in the display region. Therefore, the two ends of the gate signal line in the periphery region may introduce moisture or oxygen along the organic layer into the pixel unit, thereby affecting the display effect of the display panel.

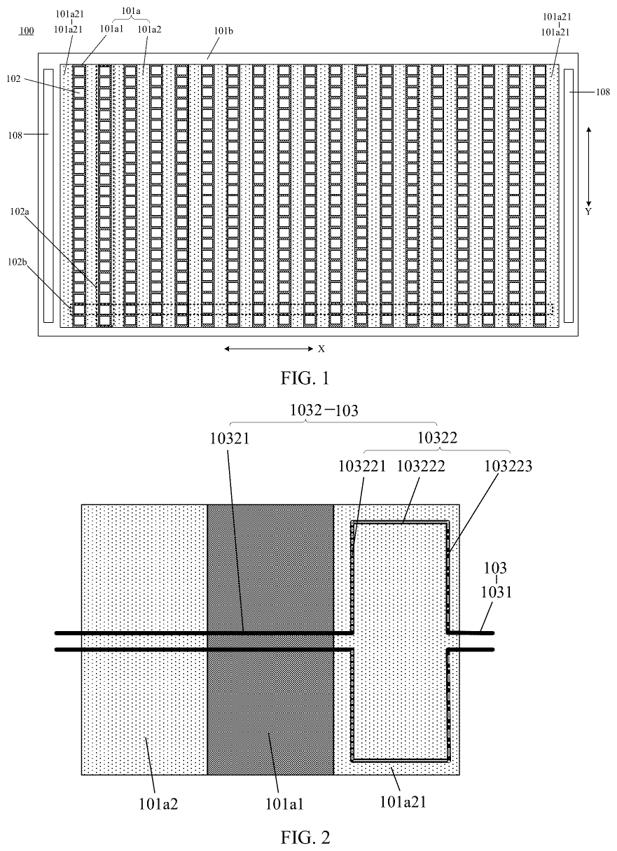

FIG. 1 is a schematic structural diagram of a display panel according to some embodiments of the present disclosure. FIG. 2 is a partial schematic structural diagram of the display panel shown in FIG. 1. In conjunction with FIG. 1 and FIG. 2, the display panel 100 includes a base substrate 101, a plurality of pixel units 102, and a plurality of gate signal lines 103.

The base substrate 101 has a display region 101a and a periphery region 101b surrounding the display region 101a. The display region 101a includes a plurality of pixel light-emitting regions 101a1 and a plurality of transparent regions 101a2. The plurality of transparent regions 101a2 includes at least one target transparent region 101a21 arranged in a first direction X. The at least one target transparent region 101a21 is disposed between the periphery region 101b and the pixel light-emitting region 101al, or disposed between two adjacent pixel light-emitting regions 101a1.

The plurality of pixel units 102 are disposed on the base substrate 101 and in the plurality of pixel light-emitting regions 101ai, and are configured to emit light. Correspondingly, as no pixel unit 102 is disposed in the transparent region 101a2, the transparent region 101a2 achieves a transparent effect. Thus, the display panel 100 is referred to as a transparent display panel.

In addition, the plurality of gate signal lines 103 are arranged in a second direction Y. The second direction Y is intersected with the first direction X. In some embodiments, the second direction Y is perpendicular to the first direction X. For example, the first direction X is a row direction of pixels in the display panel 100, and the second direction Y is a column direction of pixels in the display panel 100.

Referring to FIG. 2, the gate signal line 103 includes a first section 1031 in the periphery region 101b and a second section 1032 in the display region 101a. The second section 1032 includes a body portion 10321 extending in the first direction X and a bent portion 10322 connected to the body portion 10321. The bent portion 10322 is disposed in the target transparent region 101a21, and a path length of the bent portion 10322 is greater than a length of the target transparent region 101a21 in the first direction X.

In the embodiments of the present disclosure, as a portion of the gate signal line 103 in the target transparent region 101a21 is the bent portion 10322, and the path length of the bent portion 10322 is great, in the process of intrusion of the moisture and oxygen along the gate signal line 103 from the periphery region 101b into the pixel unit 102, the moisture and oxygen need to pass through the longer transmission path of the bent portion 10322 to intrude into the pixel unit 102, and the intrusion path is long. That is, the intrusion path of the moisture or oxygen into the pixel unit 102 is prolonged by disposing the bent portion 10322 in the gate signal line 103, and the possibility of the moisture or oxygen intruding the pixel unit 102 is reduced, such that the yield of the display panel 100 is improved, and the display effect of the display panel 100 is ensured.

In summary, the embodiments of the present disclosure provide a display panel. The display panel includes the base substrate, the plurality of pixel units, and the plurality of gate signal lines. The gate signal line includes the body portion extending in the first direction and the bent portion connected to the body portion and disposed in the target transparent region in the display region of the base substrate close to the periphery region. As the path length of the bent portion is long, the intrusion path of the moisture or oxygen into the pixel unit is long, and the possibility of the moisture or oxygen entering the pixel unit is efficiently reduced, such that the yield of the display panel is improved, and the display effect of the display panel is ensured.

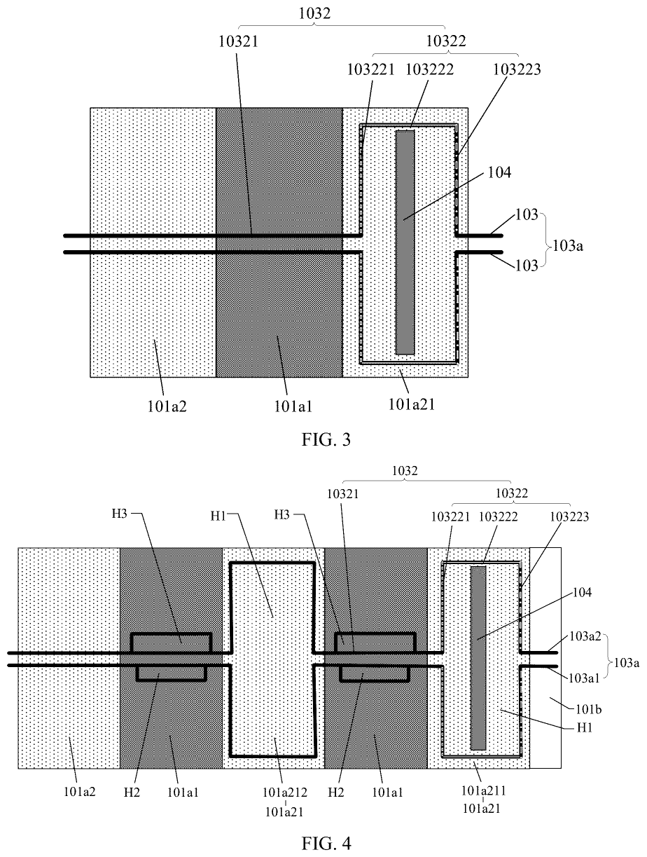

FIG. 3 is a partial schematic structural diagram of a display panel according to some embodiments of the present disclosure. Referring to FIG. 3, the display panel further includes a protection pattern 104 and a first insulation layer (the first insulation layer is not shown in FIG. 3) between the protection pattern 104 and the plurality of gate signal lines 103. The protection pattern 104 is also referred to as an electro-static discharge (ESD) structure.

The protection pattern 104 is disposed in the target transparent region 101a21 , an orthographic projection of the bent portion 10322 of the gate signal line 103 on the base substrate 101 is on a side of an orthographic projection of the protection pattern 104 on the base substrate 101, and the orthographic projection of the protection pattern 104 on the base substrate 101 is partially overlapped with the orthographic projection of the bent portion10322 of the gate signal line 103 on the base substrate 101 (overlapping is not shown in FIG. 3).

The protection pattern 104 functions to protect the gate signal line 103 to avoid the effect of the great voltage on the gate signal line 103 on the yield of the gate signal line 103. In addition, in the case that the protection pattern 104 is disposed in the periphery region 101b, a width of the frame of the display panel 100 is great. Therefore, in the embodiments of the present disclosure, the protection pattern 104 is disposed in the target transparent region 101a21 in the display region 101a without occupying the periphery region 101b, such that the width of the frame of the display panel 100 is reduced, which is conducive to the product with the narrow frame.

The bent portion 10322 of the gate signal line 103 includes a first bent portion 103221, a second bent portion 103222, and a third bent portion 103223 that are connected in sequence. The plurality of gate signal lines 103 form a plurality of signal line groups 103a. Each group of the plurality of signal line groups 103a includes two gate signal lines 103.

The first bent portion 103221 in each of the two gate signal lines 103 is disposed in a side, away from the periphery region 101b, of the protection pattern 104, and the third bent portion 103223 in each of the two adjacent gate signal lines 103 is disposed in a side, close to the periphery region 101b, of the protection pattern 104.

An orthographic projection of the second bent portion 103222 of one gate signal line 103 in the two gate signal lines 103 on the base substrate 101 is on a first side of the orthographic projection of the protection pattern 104 on the base substrate 101. An orthographic projection of the second bent portion 103222 of another gate signal line 103 in the two gate signal lines 103 on the base substrate 101 is disposed on a second side of the orthographic projection of the protection pattern 104 on the base substrate 101. The first side and the second side are two sides, arranged in the second direction, of the orthographic projection of the protection pattern 104 on the base substrate 101.

That is, in the embodiments of the present disclosure, as the bent portion 10322 of the gate signal line 103 and the protection pattern 104 are disposed in the target transparent region 101a21, for disposing of the bent portion 10322 of the gate signal line 103 and the protection pattern 104, the bend portion 10322 is connected to the pixel unit 102 in the display region 101a after bypassing the protection pattern 104 from the side of the protection pattern 104 close to the periphery region 101b.

In some embodiments, orthographic projections of bent portions 10322 of the two gate signal lines 103 in each signal line group 103a on the base substrate 101 surround the orthographic projection of the protection pattern 104 on the base substrate 101. In this case, the path length of each bent portion 10322 is greater than or equal to half of a perimeter of the protection pattern 104. As such, the path length of each bent portion 10322 is increased as much as possible, and the intrusion path of the moisture or oxygen into the pixel unit 102 is prolonged.

In the embodiments of the present disclosure, the bent portions 10322 of the two gate signal lines 103 in each signal line group 103a define a first annular region H1. The following embodiments are illustrated using an example where the first annular region H1 is a non-enclosed annular region. In some embodiments, the first annular region H1 is an enclosed annular region, which is not limited in the embodiments of the present disclosure.

Referring to FIG. 4, the two gate signal lines 103 include a first gate signal line 103a1 and a second gate signal line 103a2. A portion of the first gate signal line 103a1 in the pixel light-emitting region 101a1 has a second annular region H2, and a portion of the second gate signal line 103a2 in the pixel light-emitting region 101a1 has a third annular region H3.

An area of the first annular region H1 is greater than an area of the second annular region H2 and an area of the third annular region H3. That is, the area of the first annular region H1 is great, such that the bent portions 10322 of the two gate signal lines 103 defining the first annular region H1 is long as much as possible, and thus the intrusion path of the moisture or oxygen is prolonged.

In the embodiments of the present disclosure, the at least one target transparent region 101a21 includes a first target transparent region 101a211. The first target transparent region 101a211 is closer to the periphery region 101b than the plurality of pixel light-emitting regions 101a1. For example, a number of first target transparent regions 101a211 is two. The two first target transparent regions 101a211 refer to two transparent regions at extreme edges (for example, a leftmost side and a rightmost side) in the at least one target transparent region in the first direction X. A side, close to the periphery region, of any of the two transparent regions does not includes the pixel light-emitting region 101a1.

Furthermore, the at least one target transparent region 101a21 further includes a second target transparent region 101a212. The second target transparent region 101a212 is disposed between two adjacent pixel light-emitting regions 101a1. For example, the second target transparent region 101a212 is a transparent region in the plurality of transparent regions 101a2, and one or more pixel light-emitting regions 101al are disposed between the transparent region and the first target transparent region 101a211.

For the first annular region defined by the bent portions 10322 of the two gate signal lines 103 in the first target transparent region 101a211, a distance d1 between the first annular region and one of the plurality of pixel light-emitting regions 101a1 is greater than a distance d2 between the first annular region and the periphery region 101b (reference may be made to FIG. 27). As such, a great effect of the bent portion 10322 on the normal luminescence of the pixel light-emitting region 101a1 is avoided.

For the first annular region defined by the bent portions 10322 of the two gate signal lines 103 in the second target transparent region 101a212, the first annular region is disposed between the two pixel light-emitting regions, and distances between the second annular region and the two pixel light-emitting regions are equal. As such, effects of the bent portion 10322 on the two pixel light-emitting regions 101a1 are consistent, and thus the display uniformity of the two pixel light-emitting regions 101a1 is improved.

In the embodiments of the present disclosure, the protection pattern 104 is a stripe pattern extending in the second direction Y, and a length d3 of the protection pattern 104 in the second direction Y is greater than the distance d1 between the first annular region H1 in the first target transparent region 101a211 and one of the plurality of pixel light-emitting regions 101a1. That is, the length of the protection pattern 104 is great to avoid the poor panel due to breakdown of the protection pattern 104 at a low voltage.

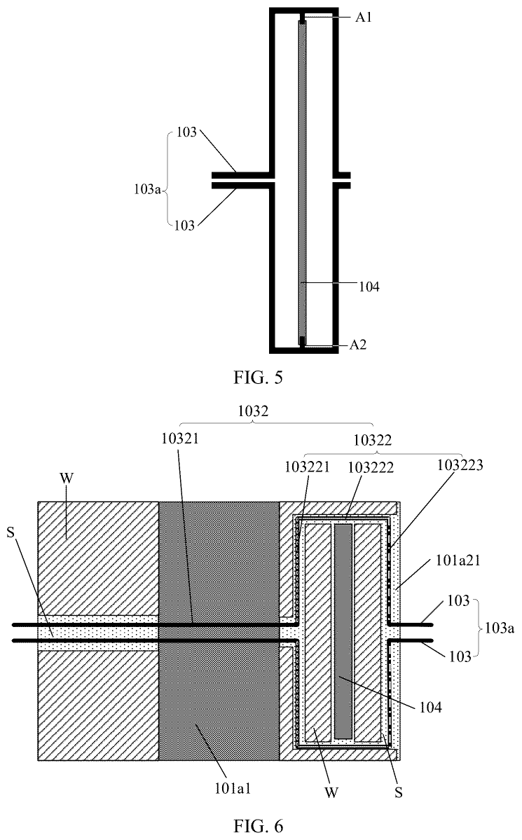

FIG. 5 is a schematic diagram of a protection pattern and bent portions of gate signal lines according to some embodiments of the present disclosure. Referring to FIG. 5, a first protrusion A1 is arranged on a side, close to the protection pattern 104, of the second bent portion 103222 of one gate signal line 103 in the two gate signal lines 103 in the signal line group 103a. An orthographic projection of a first end portion of the protection pattern 104 on the base substrate 101 is overlapped with an orthographic projection of the first protrusion A1 on the base substrate 101. A second protrusion A2 is arranged on a side, close to the protection pattern 104, of the second bent portion 103222 of another gate signal line 103 in the two gate signal lines 103 in the signal line group 103a. An orthographic projection of a second end portion of the protection pattern 104 on the base substrate 101 is overlapped with an orthographic projection of the second protrusion A2 on the base substrate 101.

In the embodiments of the present disclosure, as each of the first protrusion Al and the second protrusion A2 is overlapped with the protection pattern 104, the first protrusion Al is electrically connected to the second protrusion A2 through the protection pattern 104 at a high voltage. Illustratively, for the two gate signal lines 103 in the signal line group 103a, in the case that one gate signal line 103 is at a high voltage, the one gate signal line 103 is in communication with to the protection pattern 104, and then transmits the voltage to another gate signal line 103 through the protection pattern 104 because the protection of the second bent portion 103222 of the one gate signal line 103 is overlapped with the protection pattern 104. That is, the protection pattern 104 is disposed to balance voltages on the two gate signal lines 103 and ensure the yields of the two gate signal lines 103.

In the embodiments of the present disclosure, the display panel 100 includes a pixel unit layer. The pixel unit layer includes the plurality of pixel units 102 and a semiconductor layer between the base substrate 101 and the first insulation layer (the first insulation layer is the gate insulation layer describer hereinafter). The protection pattern 104 is disposed in the semiconductor layer, and each of the first end portion and the second end portion of the protection pattern 104 is made of a semiconductor material. In addition, a portion between the first end portion and the second end portion of the protection pattern 104 is made of a semiconductor material.

That is, in general, the first insulation layer is disposed between the gate signal line 103 and the protection pattern 104 to achieve insulation. In the case that the gate signal line 103 is at a high voltage, the semiconductor material of the first end portion and the second end portion of the protection pattern 104 conducts the protection pattern 104 and the gate signal line 103.

In the embodiments of the present disclosure, the pixel unit layer N includes a gate layer, a second insulation layer, and a cathode layer that are stacked in a direction away from the base substrate 101 in sequence. The plurality of gate signal lines 103 are disposed in the gate layer, an orthographic projection of the second insulation layer on the base substrate 101 covers orthographic projections of the plurality of gate signal lines 103 on the base substrate 101 and the orthographic projection of the protection pattern 104 on the base substrate 101.

In general, the cathode layer in the pixel unit layer N is a whole-layer film layer. In the case that the second insulation layer is not disposed between the gate signal line 103 or the protection pattern 104 and the cathode layer, a distance between the gate signal line 103 and the cathode layer in a direction perpendicular to the base substrate 101 and a distance between the protection pattern 104 and the cathode layer in the direction perpendicular to the base substrate 101 are less to prone to a large parasitic capacitance, such that the display stability of the display panel 100 is affected.

Based on above reasons, the second insulation layer is disposed between the gate signal line 103 and the cathode layer and between the protection pattern 104 and the cathode layer to increase the distance between the gate signal line 103 and the cathode layer in the direction perpendicular to the base substrate 101 and the distance between the protection pattern 104 and the cathode layer in the direction perpendicular to the base substrate 101. As such, the large parasitic capacitance generated between the gate signal line 103 and the cathode layer and the large parasitic capacitance generated between the protection pattern 104 and the cathode layer are avoided, and the display stability of the display panel 100 is improved.

In some embodiments, the cathode layer is made of indium zinc oxide (IZO) by a sputter process. In the case that the second insulation layer is not disposed between the gate signal line 103 and the cathode layer and between the protection pattern 104 and the cathode layer, a risk of static electricity may occur in the gate signal line 103 and the protection pattern 104.

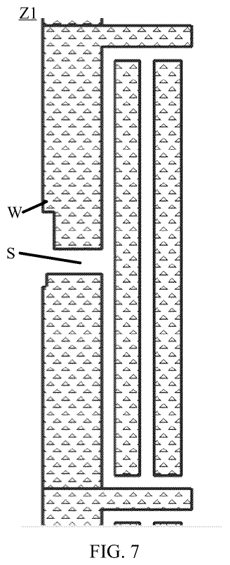

FIG. 6 is a partial schematic diagram of a display panel according to some embodiments of the present disclosure. Referring to FIG. 6, the second insulation layer includes a material region S containing an insulative material and a void region W without any insulative material.

The material region S is disposed in the plurality of pixel light-emitting regions 101a1, and an orthographic projection of the material region S on the base substrate 101 covers the orthographic projection of the protection pattern 104 on the base substrate 101 and the orthographic projections of the plurality of gate signal lines 103 on the base substrate 101. As the material region S in the second insulation layer is disposed in the plurality of pixel light-emitting regions 101a1, film layers of the pixel units in the plurality of pixel light-emitting regions 101a1 are insulative. As the material region S in the second insulation layer is disposed in the gate signal line 103 and the protection pattern 104, the distance between the gate signal line 103 (the protection pattern 104) and the cathode layer in the direction perpendicular to the base substrate 101 is increased, and the parasitic capacitance is reduced.

In addition, the void region W in the second insulation layer is disposed on a side, away from the orthographic projection of the protection pattern 104 on the base substrate 101, of the orthographic projections of the plurality of gate signal lines 103 on the base substrate 101, disposed between the orthographic projections of the plurality of gate signal lines 103 on the base substrate 101 and the orthographic projection of the protection pattern 104 on the base substrate 101, and disposed in other regions of the plurality of transparent regions 101a2 than regions of the orthographic projections of the plurality of gate signal lines 103 on the base substrate 101. That is, other regions including the protection pattern 104 and the plurality of gate signal lines 103 than the plurality of pixel light-emitting regions 101a1 are the void region W.

It should be noted that the display panel 100 according to the embodiments of the present disclosure is a transparent display panel. As the display panel includes many film layers, and each film layer affects the transparence of the display panel 100, the void region W is disposed in the second insulation layer to reduce the effect of the second insulation layer on the transparence of the display panel 100, such that the number of stacked film layers in the display panel is reduced, and the transparent display effect of the display panel 100 is ensured.

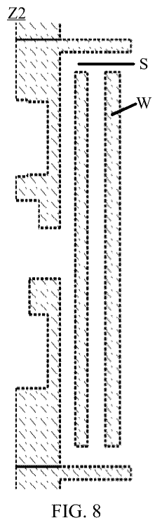

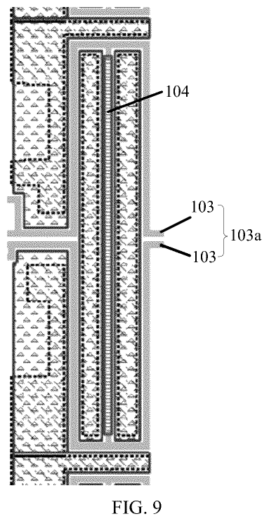

In some embodiments, referring to FIG. 7 to FIG. 9, the second insulation layer at least includes a first insulation sub-layer Z1 and a second insulation sub-layer Z2 that are stacked in the direction away from the base substrate 101 in sequence. A boundary of an orthographic projection of the first insulation sub-layer Z1 on the base substrate 101 is not overlapped with a boundary of an orthographic projection of the second insulation sub-layer Z2 on the base substrate 101. The boundary of the orthographic projection of the first insulation sub-layer Z1 on the base substrate 101 being not overlapped with the boundary of the orthographic projection of the second insulation sub-layer Z2 on the base substrate 101 means that a boundary of an orthographic projection of the material region in the first insulation sub-layer Z1 on the base substrate 101 is not overlapped with a boundary of an orthographic projection of the material region in the second insulation sub-layer Z2 on the base substrate 101, and a boundary of an orthographic projection of the void region in the first insulation sub-layer Z1 on the base substrate 101 is not overlapped with a boundary of an orthographic projection of the void region in the second insulation sub-layer Z2 on the base substrate 101.

Illustratively, the first insulation sub-layer Z1 is a planarization layer (resin) in the display panel 100, and the second insulation sub-layer Z2 is a pixel define layer in the display panel 100. As the boundaries of the of the two insulation sub-layers are not overlapped, an effect of an excessive step of the film layer at the boundary of the insulation sub-layer on manufacturing of the cathode layer is avoided, and fracture of the cathode layer is avoided.

In the embodiments of the present disclosure, each of the plurality of pixel light-emitting regions 101a1 and the plurality of transparent regions 101a2 is a stripe region extending in the second direction Y, the plurality of pixel light-emitting regions 101a1 and the plurality of transparent regions 101a2 are staggered in the first direction X. The plurality of transparent regions 101a2 include two target transparent regions 101a21, and the plurality of pixel light-emitting regions 101a1 and other transparent regions 101a2 in the plurality of transparent regions 101a2 than the two target transparent regions 101a21 are disposed between the two target transparent regions 101a21. That is, regions closest to the periphery region 101b on two sides of the display region 101a in the first direction X are all transparent regions 101a2.

Each of the plurality of gate signal lines 103 includes two bent portions 10322. One of the two bent portions 10322 is connected to an end of the body portion 10321 and is disposed in one target transparent region 101a21 in the two target transparent regions 101a21, and another bent portion 10322 in the two bent portions 10322 is connected to another end of the body portion 10321 and is disposed in another target transparent region 101a21 in the two target transparent regions 101a21. That is, two ends of the gate signal line 03 in the first direction X are approximately symmetrical.

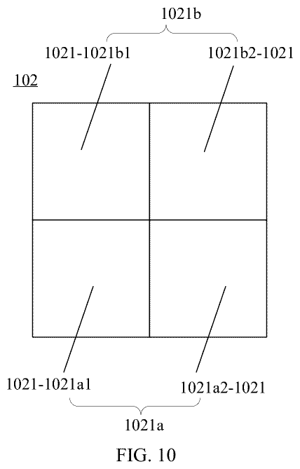

In the embodiments of the present disclosure, each pixel unit 102 is connected to two gate signal lines 103 in one group of the plurality of signal line groups 103a formed by the plurality of gate signal lines 103. The two gate signal lines 103 include the first gate signal line 103a1 and the second gate signal line 103a2. Referring to FIG. 10, each of the plurality of pixel units 102 in the display panel 100 includes a plurality of sub-pixels 1021, and each of the plurality of sub-pixels 1021 includes a pixel circuit 10211 and a light-emitting unit 10212.

Illustratively, the plurality of sub-pixels 1021 in each of the plurality of pixel units 102 includes red sub-pixels (R), green sub-pixels (G), and blue sub-pixels (B). Furthermore, the plurality of sub-pixels 1021 in each of the plurality of pixel units 102 further includes white sub-pixels (W). The pixel unit shown in FIG. 10 includes four sub-pixels 1021.

For each sub-pixel 1021, the pixel circuit 10211 in each sub-pixel 1021 is connected to the light-emitting unit 10212 in each sub-pixel 1021 to supply a drive signal to the light-emitting unit 10212. The light-emitting unit 10212 is configured to emit light under driving of the drive signal.

In some embodiments, the pixel circuit 10211 includes a plurality of thin-film transistors (TFT) and at least one storage capacitor. For example, the embodiments of the present disclosure are illustrated using an example where the pixel circuit 10211 includes three thin-film transistors and one storage capacitor, that is, the pixel circuit 10211 is a 3T1C pixel circuit. Alternatively, the pixel circuit 10211 includes another number of thin-film transistors and another number of storage capacitors C. The embodiments of the present disclosure do not limit the number of thin-film transistors and the number of storage capacitors C in the pixel circuit 10211.

Each thin-film transistor includes a gate, a source, and a drain. The plurality of thin-film transistors in the pixel circuit 10211 are connected to each other to drive the light-emitting unit 10212 to emit light.

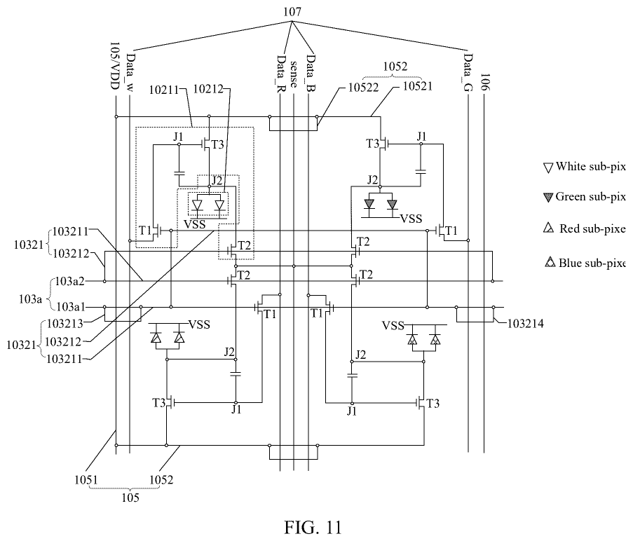

FIG. 11 is an equivalent circuit diagram of a pixel circuit of a sub-pixel according to some embodiments of the present disclosure. Referring to FIG. 11, the pixel circuit 10211 includes a first transistor T1, a second transistor T2, a third transistor T3, and a storage capacitor C.

A gate electrode of the first transistor T1 is connected to the first gate signal line 103a1, a first electrode of the first transistor T1 is connected to a data signal line, and a second electrode of the first transistor T1 is connected to a first node J1.

A gate electrode of the second transistor T2 is connected to the second gate signal line 103a2, a first electrode of the second transistor T2 is connected to a sensing signal line, and a second electrode of the second transistor T2 is connected to a second node J2.

A gate electrode of the third transistor T3 is connected to the first node J1, a first electrode of the third transistor T3 is connected to a first power line 105, and a second electrode of the third transistor T3 is connected to the second node J2.

A first electrode of the storage capacitor C is connected to the first node J1, and a second electrode of the storage capacitor C is connected to the second node J2.

In the embodiments of the present disclosure, the second transistor T2 is referred to as a sensing transistor, and the third transistor T3 is referred to as a driving transistor. The sensing transistor is connected to the second node J2, and the driving transistor is also connected to the second node J2. The sensing transistor is configured to reset an initial potential of the second node J2 and detect a threshold voltage of the driving transistor in time, such that the initial potential of the second electrode of the driving transistor keeps stable, and the threshold voltage of the driving transistor is compensated upon detection of the threshold voltage of the driving transistor. Thus, the luminance of the light-emitting unit 10212 is not affected by the threshold voltage of the driving transistor, and the luminance of the light-emitting unit 10212 keeps stable.

In the embodiments of the present disclosure, the second node J2 may be a lapping point of the pixel circuit 10211 and the light-emitting unit 10212. That is, the second node J2 is also connected to the anode pattern of the light-emitting unit 10212.

In some embodiments, a distance between the second node J2 and a first annular region is greater than or equal to a distance between the first annular region and one of the plurality of pixel light-emitting regions. That is, a distance between the lapping point and the first annular region is great to avoid an effect of entering of the moisture or oxygen in the first annular region into the lapping point on the light-emitting unit.

Illustratively, for the first target transparent region 101a211, a number of pixel light-emitting regions 101a1 adjacent to the first target transparent region 101a211 is one. As such, for the first annular region in the first target transparent region 101a211, the distance between the second node J2 and the first annular region is greater than or equal to the distance between the first annular region and the adjacent pixel light-emitting region.

For the second target transparent region 101a211, a number of pixel light-emitting regions 101a1 adjacent to the second target transparent region 101a211 is two. As such, for the first annular region in the second target transparent region 101a211, the distance between the second node J2 and the first annular region is greater than or equal to the distance between the first annular region and any of the adjacent pixel light-emitting regions.

The embodiments of the present disclosure are illustrated using an example where the pixel unit 102 includes a red sub-pixel, a green sub-pixel, a blue sub-pixel, and a white sub-pixel, and the sub-pixel 1021 of each color includes three thin-film transistors and one storage capacitors C. in conjunction within FIG. 1 and FIG. 11, the plurality of pixel units 102 are arranged in an array and include a plurality of first pixel unit groups 102a arranged in the second direction Y. Each group of the plurality of first pixel unit groups 102a includes multiple pixel units 102 arranged in the first direction X.

Each of the plurality of gate signal lines 103 is connected to the multiple pixel units 102 in one group of the plurality of first pixel unit groups 102a, and the multiple pixel units 102 in each group of the plurality of first pixel unit groups 102a are connected to two gate signal lines 103 in one group of a plurality of signal line groups 103a formed by the plurality of gate signal lines 103.

The signal line group 103a refers to a row of pixel units, and each row of pixel units corresponds to two gate signal lines 103 in one signal line group 103a. As shown in FIG. 11, the first transistor T1 in the pixel circuit 10211 is connected to the first gate signal line 103a1 in the signal line group 103a, and the second transistor T2 in the pixel circuit 10211 is connected to the second gate signal line 103a2 in the signal line group 103a.

In the embodiments of the present disclosure, referring to FIG. 10, the pixel unit 102 includes a first group of sub-pixels 1021a and a second group of sub-pixels 1021 b that are arranged in the second direction Y to convenient connection between the sub-pixels 1021 in the pixel unit 102 and the signal line group 103a. The first group of sub-pixels 1021a includes at least one sub-pixel 1021, the second group of sub-pixels 1021b includes at least one sub-pixel 1021. For example, in FIG. 10, the first group of sub-pixels 1021a and the second group of sub-pixels 1021b each include two sub-pixels 1021. The embodiments of the present disclosure are illustrated using an example where the first group of sub-pixels 1021a includes a red sub-pixel and a blue sub-pixel, and the second group of sub-pixels 1021b includes a white sub-pixel and a green sub-pixel.

In some embodiments, each sub-pixel 1021 in each pixel unit 102 needs to be connected to two gate signal lines 103 in the signal line group 103a corresponding to the pixel unit 102. Illustratively, the white sub-pixel needs to be connected to the first gate signal line 103al1 and the second gate signal line 103a2, the green sub-pixel needs to be connected to the first gate signal line 103a1 and the second gate signal line 103a2, the red sub-pixel needs to be connected to the first gate signal line 103a1 and the second gate signal line 103a2, and the blue sub-pixel needs to be connected to the first gate signal line 103a1 and the second gate signal line 103a2.

For convenient connection between each sub-pixel 1021 and two gate signal lines 103 in the signal line group 103a, it can be seen referring to FIG. 11 that body portions 10321 of the two gate signal lines 103 connected to the multiple pixel units 102 in each group of the plurality of first pixel unit groups 102a are disposed between the first group of sub-pixels 1021a and the second group of sub-pixels 1021b.

In addition, referring to FIG. 11, the body portion 10321 of the gate signal line 103 includes a first primary path line 103211 and a plurality of first secondary path lines 103212. Two ends of each of the plurality of first secondary path lines 103212 are connected to the first primary path line 103211. Each of the plurality of first secondary path lines 103212 and the first primary path line 103211 form an annular region in the pixel light-emitting region 101a1.

Illustratively, for the first gate signal line 103a1 in FIG. 11, the first secondary path line 103212 and the first primary path line 103211 form a second annular region H2 in the pixel light-emitting region 101a1. For the second gate signal line 103a2 in FIG. 11, the first secondary path line 103212 and the first primary path line 103211 form a third annular region H3 in the pixel light-emitting region 101a1. Referring to FIG. 11, shapes and sizes of the second annular region H2 and the third annular region H3 are different, and may be the same in some embodiments, which is not limited in the embodiments of the present disclosure.

Referring to FIG. 11, the first primary path line 103211 in the gate signal line 103 is connected to sub-pixels 1021 in first groups of sub-pixels 1021a of the multiple pixel units 102 in one group of the plurality of first pixel unit groups 102a, and each of the plurality of first secondary path lines 103212 is connected to the sub-pixel 1021 in the second group of sub-pixels 1021b of one of the multiple pixel units 102.

Illustratively, for the first gate signal line 103a1 in FIG. 11, the first primary path line 103211 is closer to the first group of sub-pixels 1021a than the first secondary path line 103212, and the first primary path line 103211 is connected to the red sub-pixel and the blue sub-pixel in the first group of sub-pixels 1021a. The first secondary path line 103212 is closer to the second group of sub-pixels 1021b than the first primary path line 103211, and the first secondary path line 103212 is connected to the white sub-pixel and the green sub-pixel in the second group of sub-pixels 1021b.

Similarly, for the second gate signal line 103a2 in FIG. 11, the first primary path line 103211 is closer to the first group of sub-pixels 1021a than the first secondary path line 103212, and the first primary path line 103211 is connected to the red sub-pixel and the blue sub-pixel in the first group of sub-pixels 1021a. The first secondary path line 103212 is closer to the second group of sub-pixels 1021b than the first primary path line 103211, and the first secondary path line 103212 is connected to the white sub-pixel and the green sub-pixel in the second group of sub-pixels 1021b.

As the gate signal line 103 includes two paths, in the case of a short circuit between one of the path line of the gate signal line 103 and another signal line, the one of the path line is cut off, such that only luminescence of the sub-pixels connected to the path line are affected, and other sub-pixels are not affected. Thus, the display effect of the display panel 100 is ensured as much as possible.

It should be noted that in cutting off the path line, a portion between two connection positions between two ends of the first secondary path line 103212 and the first primary path line 103211 is cut off. In the case that the first secondary path line 103212 is short-circuited, the first secondary path line 103212 is cut off at any position between two ends of the first secondary path line 103212, and the gate signal line 103 transmits the signal to the adjacent pixel unit 102 in the first direction X along the first primary path line 103211. In the case that the first primary path line 103211 is short-circuited, the first primary path line 103211 is cut off at any position between the two connection positions, and the gate signal line 103 transmits the signal to the adjacent pixel unit 102 in the first direction X along the first primary path line 103211.

In the embodiments of the present disclosure, referring to FIG. 1, the plurality of pixel units 102 include a plurality of second pixel unit groups 102b arranged in the first direction X. Each group of the plurality of second pixel unit groups 102b includes multiple pixel units 102 arranged in the second direction Y.

Furthermore, the display panel 100 includes a plurality of first power lines 105 (also referred to as VDD traces) corresponding to the plurality of second pixel unit groups 102b, and a plurality of corresponding auxiliary electrode lines 106. FIG. 11 shows a pixel unit 102, a first power line 105, and an auxiliary electrode line 106.

Referring to FIG. 11, each of the plurality of first power lines 105 includes a primary power line 1051 and a plurality of branch power lines 1052. The plurality of branch power lines 1052 are connected to the primary power line 1051, and the primary power line 1051 is disposed on a side of a corresponding second pixel unit group 102b. For example, as shown in FIG. 11, the primary power line 1051 is disposed on a left side of the second pixel unit group 102b. Each of the plurality of first power lines 105 is connected to sub-pixels 1021 in the multiple pixel units 102 in one group of the plurality of second pixel unit groups 102b. That is, the first power line 105 supplies the first power signal to various sub-pixels 1021 in the pixel units 102 in the corresponding second pixel unit group 102b.

Illustratively, the pixel unit 102 in FIG. 11 includes a first group of sub-pixels 1021a and a second group of sub-pixels 1021b, that is, two groups of sub-pixels. For each pixel unit 102, the pixel unit 102 corresponds to two branch power lines 1052, one branch power line 1052 in the two branch power lines 1052 is connected to the sub-pixels 1021 in the first group of sub-pixels 1021a, another branch power line 1052 in the two branch power lines 1052 is connected to the sub-pixels 1021 in the second group of sub-pixels 1021b.

Each of the plurality of auxiliary electrode lines 106 is disposed on another side of the corresponding second pixel unit group 102b and is connected to a cathode layer in the multiple pixel units 102.

It can be seen referring to FIG. 11 that for the primary power line 1051 of a first power line 105 and an auxiliary electrode line 106 that correspond to the second pixel unit group 102b, in two connection positions between two ends of the first secondary path line 103212 of the first gate signal line 103a1 and the first primary path line 103211, one connection position is disposed on a side, away from the auxiliary electrode line 106, of the primary power line 1051, and another connection position is disposed on a side, away from the primary power line 1051, of the auxiliary electrode line 106.

That is, the primary power line 1051, the auxiliary electrode line 106, regions of other signal lines between the primary power line 1051 and the auxiliary electrode line 106, and the first gate signal lien 103a1 include the first primary path line 103211 and the first secondary path line 103212. As the primary power line 1051, the auxiliary electrode line 106, and other signal lines may be short-circuited with the first gate signal lien 103a1, the short-circuit is efficiently avoided by disposing two paths.

It can be seen referring to FIG. 11 that for the primary power line 1051 of a first power line 105 and an auxiliary electrode line 106 that correspond to the second pixel unit group 102b, two connection positions between two ends of the first secondary path line of the second gate signal line 103a2 and the first primary path line 103211, one connection position are disposed between the primary power line 1051 and the auxiliary electrode line 106.

That is, the gate signal line 103 includes single path in the region of the primary power line 1051 and the auxiliary electrode line 106, and the gate signal line 103 includes two paths in the regions of other signal lines between the primary power line 1051 and the auxiliary electrode line 106. As such, in the case that the gate signal line 103 is short-circuited with the primary power line 1051 or the auxiliary electrode line 106, the short circuit is not avoided by cutting off one path.

Thus, referring to FIG. 11, the body portion 10321 further includes a plurality of second secondary path lines 103213 and a plurality of third secondary path lines 103214. Two ends of each of the plurality of second secondary path lines 103213 are connected to the first primary path line 103211, and two connection positions between the two ends of each of the plurality of second secondary path lines 103213 and the first primary path line 103211 are disposed on two side of the primary power line 1051. Two ends of each of the plurality of third secondary path lines 103214 are connected to the first primary path line 103211, and two connection positions between the two ends of each of the plurality of third secondary path lines 103214 and the first primary path line 103211 are disposed on two side of the one of the plurality of auxiliary electrode lines 106.

That is, for the second gate signal line 103a2 shown in FIG. 11, the second secondary path line 103213 and the third secondary path line 103214 are required, such that the region of the primary power line 1051 and the region of the auxiliary electrode line 106 each include two paths. As such, in the case that the gate signal line 103 is short-circuited with the primary power line 1051, the short circuit is avoided by cutting off the second secondary path line 103213 or cutting off a portion of the first primary path line 103211 between two connection positions between the first primary path line 103211 and the second secondary path line 103213. In the case that the gate signal line 103 is short-circuited with the auxiliary electrode line 106, the short circuit is not avoided by cutting off the third secondary path line 103214 or cutting off a portion of the primary path line 103211 between two connection positions between the first primary path line 103211 and the third secondary path line 103214.

In the embodiments of the present disclosure, referring to FIG. 11, the display panel further includes a plurality of data line groups 107 corresponding to the plurality of second pixel unit groups 102b. Each group of the plurality of data line groups 107 includes a plurality of data signal lines arranged in the first direction X. The plurality of data signal lines extend in the second direction Y.

For convenient layout, some of the plurality of data signal lines in each group of the plurality of data line groups 107 are disposed between the first sub-pixel 1021a1 and the second sub-pixel 1021a2, and between the third sub-pixel 1021b 1 and the fourth sub-pixel 1021b2. In addition to the data signal lines disposed in the middle portion, other data lines are disposed on two sides of the pixel unit 102.

Illustratively, the pixel unit 102 in the embodiments of the present disclosure include four different types of sub-pixels 1021, and the corresponding data line group 107 includes four data signal lines. Two of the four data signal lines (referred to as the target data line) are disposed between the first sub-pixel 1021a1 and the second sub-pixel 1021a2, and between the third sub-pixel 1021b1 and the fourth sub-pixel 1021b2. One of another two of the four data signal lines is disposed on a side, away from the second sub-pixel 1021a2, of the first sub-pixel 1021a1 and on a side, away from the fourth sub-pixel 1021b2, of the third sub-pixel 1021b1, and another of the another two of the four data signal lines is disposed on a side, away from the first sub-pixel 1021a1 of the second sub-pixel 1021a2 and on a side, away from the third sub-pixel 1021b, of the fourth sub-pixel 1021b2.

Specifically, assuming that the four data signal lines in the data line group 107 is a first data signal line (Data_R), a second data signal line (Data_B), a third data signal line (Data_w), and a fourth data signal line (Data_G).

The first data signal line (Data_R), the sensing signal line (sense), the second data signal line are arranged in the first direction X, and disposed are disposed between the first sub-pixel 1021a1 and the second sub-pixel 1021a2 and between the third sub-pixel 1021b1 and the fourth sub-pixel 1021b2, the first data signal line (Data_R) is connected to the first sub-pixel 1021a1, and the second data signal line (Data_B) is connected to the second sub-pixel 1021a2 and is configured to supply a data drive signal to the second sub-pixel 1021a2.

The third data signal line (Data_w) is disposed on a side of a corresponding second pixel unit group 102b, and is connected to the third sub-pixel 1021b1 and is configured to supply a data drive signal to the third sub-pixel 1021b1.

The fourth data signal line (Data_G) is disposed on another side of the corresponding second pixel unit group 102b, and is connected to the fourth sub-pixel 1021b2 and is configured to supply a data drive signal to the fourth sub-pixel 1021b2.

In addition, the sensing signal line (sense) is connected to the first sub-pixel 1021a1, the second sub-pixel 1021a2, the third sub-pixel 1021b1, and the fourth sub-pixel 1021b2, and is configured to supply a sensing signal to the four sub-pixels 1021.

In the embodiments of the present disclosure, as each first power line 105 needs to supply a first power signal to each sub-pixel 1021 in the plurality of pixel unit 102 in the second pixel unit group 102b, the branch power line 1052 of the first power line 105 needs to cross the target data signal line and the sensing signal line, and is connected to the sub-pixels 1021 on two sides of the target data signal line and the sensing signal line.

As the first power line 105 may be short-circuited with the target data signal line and the sensing signal line, two paths are disposed to avoid the possibility of the short circuit.

In some embodiments, the branch power line 1052 includes a second primary path line 10521 and a fourth secondary path line 10522. Two ends of the fourth secondary path line 10522 are connected to the second primary path line 10521, and two connection positions between the two ends of the fourth secondary path line 10522 and the second primary path line 10521 are disposed on two sides of the target data signal line. That is, the first power line 105 includes two paths in the region of the target data signal line and the region of the sensing signal line.

In the case that one path line of the branch power line 1052 is short-circuited with the target data signal line (or the sensing signal line), the path line is cut off. As another path line is still conducted, transmission of the first power signal by the first power line 105 is not affected.

It should be noted that in cutting off the path line, a portion between two connection positions between two ends of the second secondary path line 103213 and the fourth secondary path line 10522 is cut off. In the case that the fourth secondary path line 10522 is short-circuited, the fourth secondary path line 10522 is cut off at any position between two ends of the fourth secondary path line 10522, and the first power line 105 transmits the first power signal to the sub-pixel 1021 along the second primary path line 10521. In the case that the second primary path line 10521 is short-circuited, the second primary path line 10521 is cut off at any position between the two connection positions, and the gate signal line 103 transmits the first power signal to the sub-pixel 1021 along the fourth secondary path line 10522.

In the embodiments of the present disclosure, the auxiliary electrode line 106 in the display panel is the second power line (the VSS trace), and the second power line is connected to the cathode layer in the pixel unit 102 and is configured to supply a second power signal to the cathode layer. In some embodiments, at least one data signal line is disposed between the primary power line 1051 and the second power line. As the a difference between a potential of the first power line 105 and a potential of the second power line is great, at least one data signal line is disposed between the first power line 105 the second power line to avoid the short circuit between the first power line 105 the second power line.

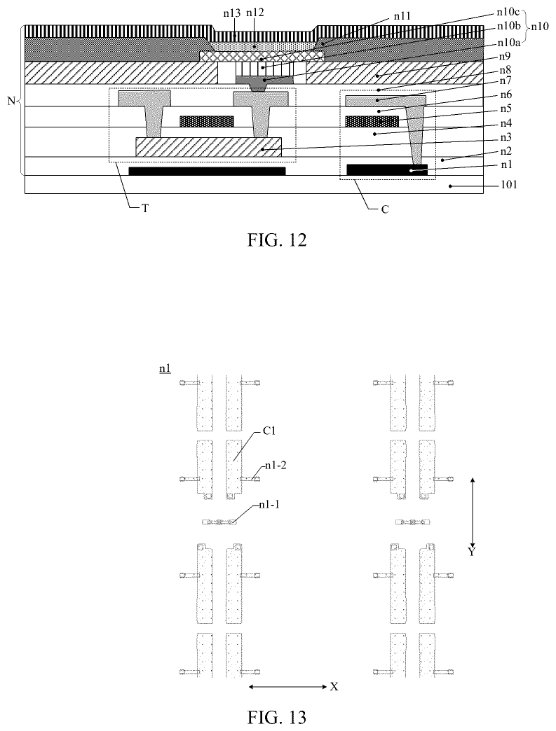

FIG. 12 is a local section view of a display panel according to some embodiments of the present disclosure. Referring to FIG. 12, it can be seen that the display panel 10 includes a pixel unit layer N on the base substrate 101. The pixel unit layer N includes pixel circuits 10211 of the plurality of sub-pixels 1021, and light-emitting units 10212 of the plurality of sub-pixels 1021.

In some embodiments, the pixel unit layer N includes a light-shielding layer n1, a buffer layer n2, a semiconductor layer n3, a gate insulation layer (GI) n4, a gate layer n5, an interlayer dielectric layer (IDL) n6, a source and drain layer n7, a passivation layer (PVX) n8, a planarization layer (PLN) n9, an anode layer n10, a pixel define layer n11, a light-emitting layer n12, and a cathode layer n13 that are stacked in the direction away from the base substrate 101 in sequence. The protection pattern 104 is disposed in the semiconductor layer, and the gate signal line 103 is disposed in the gate layer.

In some embodiments, the anode film layer n10 includes a first anode film layer n10a, a second anode film layer n10b, and a third anode film layer n10c that are stacked in sequence. The first anode film layer n10a and the second anode film layer n10b are made of indium tin oxide (ITO), and the third anode film layer n10c is made of ITO and cuprum (Cu) and is referred to as a reflection anode film layer.

It should be noted that FIG. 12 only shows stack relationship pf various film layers, and is not intended to show sections of specific positions in the display panel and connection relationship of transistors in the pixel circuit 10211 in the display panel. FIG. 12 shows a thin-film transistor and a storage capacitor C, and the storage capacitor C includes a first capacitor plate C1 in the light-shielding layer and the source and drain layer, and a second capacitor plate C2 in the gate layer.

For clear description of various film layers in the display panel 100, various film layers in three transistors and one storage capacitor C in the pixel circuit 10211 are described by the stepwise stack mode.

FIG. 13 is a partial schematic diagram of a light-shielding layer according to some embodiments of the present disclosure. It can be seen referring to FIG. 13 that the light-shielding layer n1 includes the first capacitor plate C1 of the storage capacitor C and the light-shielding portion n1-1. The light-shielding portion n1-1 is configured to shield a channel of the transistor to avoid the effect of the light on the transistor. The first capacitor plate C1 further includes a capacitor connection portion n1-2. The capacitor connection portion n1-2 is configured to be connected to the subsequently formed anode layer to form the second node J2.

The display panel includes the buffer layer n2 on a side, away from the base substrate 101, of the light-shielding layer, and the buffer layer n2 is configured to insulate the light-shielding layer n1 from the subsequently formed semiconductor layer n3.

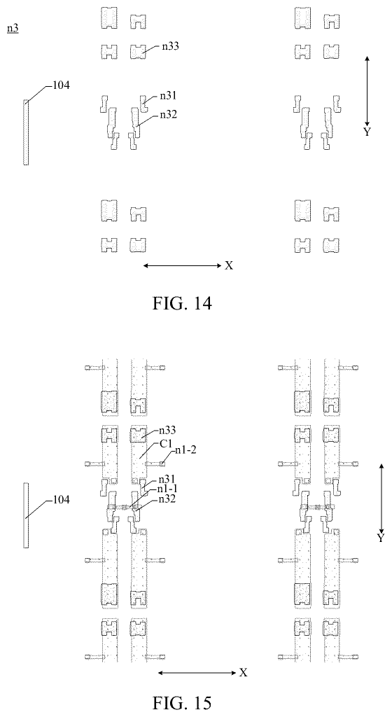

FIG. 14 is a partial schematic diagram of a semiconductor layer according to some embodiments of the present disclosure. FIG. 15 is a partial schematic diagram of stack of a light-shielding layer and a semiconductor layer according to some embodiments of the present disclosure. Referring to FIG. 14 and FIG. 15, the semiconductor layer is in a curved or bent shape, and includes semiconductor patterns (a channel region) and doping region patterns (a source and drain doping region) of various transistors, and the semiconductor pattern and the and doping region pattern of various transistors in the same pixel circuit 10211 are integrated.

It should be noted that the semiconductor layer includes a low-temperature polysilicon layer, and electrical connection of various structures is achieved by conducting, such as by doping, the source region and the drain region. That is, the semiconductor layer in various transistors of the pixel circuit 10211 is a pattern formed by p-Si, various transistors in the same pixel circuit 10211 include the doping region patterns (that is, the source region and the drain region) and the semiconductor patterns, and the semiconductor patterns of different transistors are spaced apparat from each other. For example, in FIG. 14, the semiconductor layer n3 includes a semiconductor pattern n31 of a first transistor T1, a semiconductor pattern n32 of a second transistor T2, and a semiconductor pattern n33 of a second transistor T3. In addition, the semiconductor patterns of second transistors T2 in two sub-pixels adjacent in the second direction Y in the pixel unit 102 are integrated.

The semiconductor layer is made of an amorphous silicon material, a polysilicon material, an oxide semiconductor material, and the like. It should be noted that the source region and the drain region are a region doped with n-type or p-type impurities.

Furthermore, the semiconductor layer further includes the protection pattern 104. The protection pattern 104. The protection pattern 104 is a stripe structure extending in the second direction Y. In addition, the display panel includes a gate insulation layer on a side, away from the base substrate 101, of the semiconductor layer, and the gate insulation layer is configured to insulate the semiconductor layer from the subsequently formed gate layer.

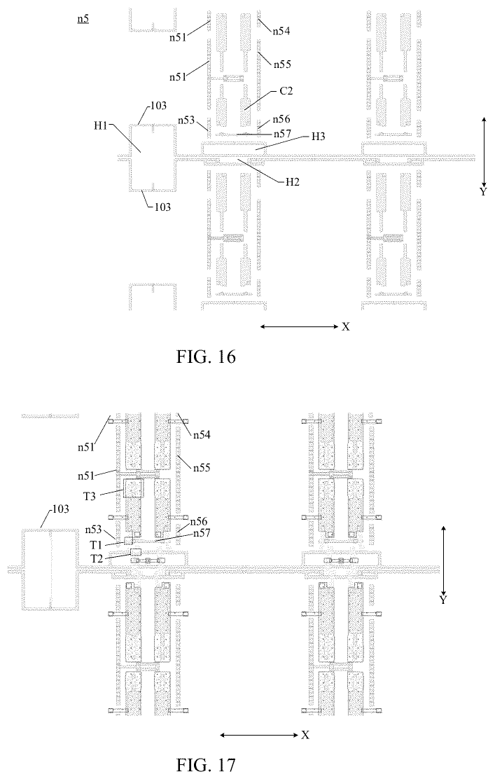

FIG. 16 is a partial schematic diagram of a gate layer in a display panel according to some embodiments of the present disclosure. FIG. 17 is a partial schematic diagram of stack of a light-shielding layer, a semiconductor layer, and a gate layer according to some embodiments of the present disclosure. Referring to FIG. 16 and FIG. 17, the gate layer n5 includes the following portions.

The gate layer n5 includes a second capacitor plate C2, a first gate portion n51, a second gate portion n52, a third gate portion n53, a fourth gate portion n54, a fifth gate portion n55, a sixth gate portion n56, and a seventh gate portion n57.

The first gate portion n51, the second gate portion n52, and the third gate portion n53 are spaced apart from each other in the second direction Y, and are configured to be connected to the first power line 105 in the subsequently formed source and drain layer. That is, a resistance of the first power line 105 is reduced by disposing the first power line 105 in two layers. In addition, the space between the first gate portion n51 and the second gate portion n52 and the space between the second gate portion n52 and the third gate portion n53 are for avoid the capacitor connection portion n1-2 in the light-shielding layer n1, such that the orthographic projections thereof are not overlapped to avoid the short circuit due to overlapping.

The fourth gate portion n54, the fifth gate portion n55, and the sixth gate portion n56 are spaced apart from each other in the second direction Y, and are configured to be connected to the auxiliary electrode line 106 in the subsequently formed source and drain layer. That is, a resistance of the auxiliary electrode line 106 is reduced by double-layer wiring of the auxiliary electrode layer 106. In addition, the space between the fourth gate portion n54 and the fifth gate portion n55 and the space between the fifth gate portion n55 and the sixth gate portion n56 are for avoid the capacitor connection portion n1-2 in the light-shielding layer n1, such that the orthographic projections thereof are not overlapped to avoid the short circuit due to overlapping.

The seventh gate portion n57 acts as the gate pattern of the first transistor T1, and the gate patterns of the first transistors T1 in two sub-pixels adjacent in the first direction X in the pixel unit 102 are integrated.

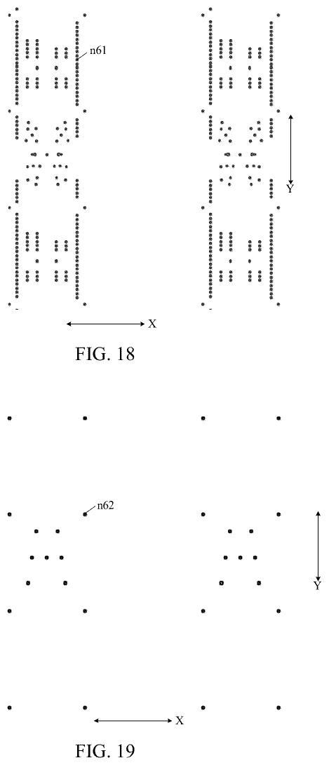

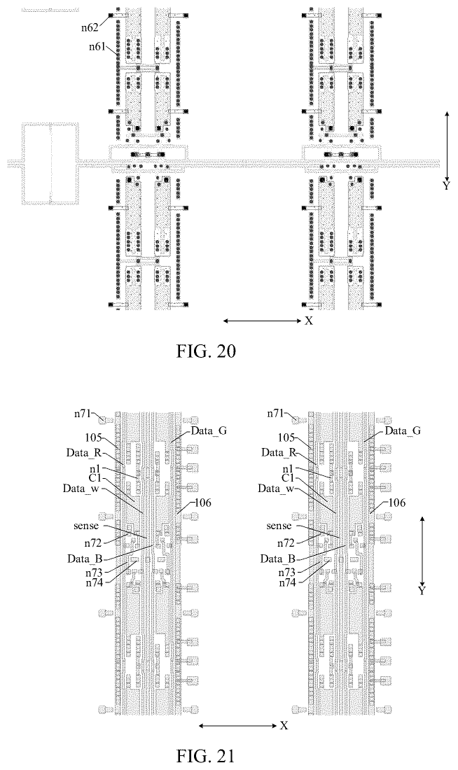

FIG. 18 is a partial schematic diagram of an interlayer dielectric layer according to some embodiments of the present disclosure. FIG. 19 is a partial schematic diagram of an interlayer dielectric layer according to some embodiments of the present disclosure. FIG. 20 is a partial schematic diagram of stack of a light-shielding layer, a semiconductor layer, a gate layer, and an interlayer dielectric layer according to some embodiments of the present disclosure.

In the embodiments of the present disclosure, some of patterns subsequently formed in the source and drain layer need to be connected to patterns in the light-shielding layer n1 through the vias in the interlayer dielectric layer n6, and some of patterns need to be connected to the patterns in the semiconductor layer n3 and patterns in the gate layer n5 through the vias in the interlayer dielectric layer n6.

As a distance between the light-shielding layer and the source and drain layer n7 in the direction perpendicular to the base substrate 101 is great, a depth of the via needs to be great. As the vias in the interlayer dielectric layer are manufactured using a double mask plate. Position of the vias n61 first formed are shown in FIG. 18, and positions of the vias n62 second formed are shown in FIG. 19. The vias n62 shown in FIG. 19 are formed to second etch some vias n61 formed in FIG. 18, such that the via n62 deeper than the via n61 is formed.

It should be noted that in FIG. 18 to FIG. 20, circles represent the vias, and other regions represent regions with the material in the interlayer dielectric layer.

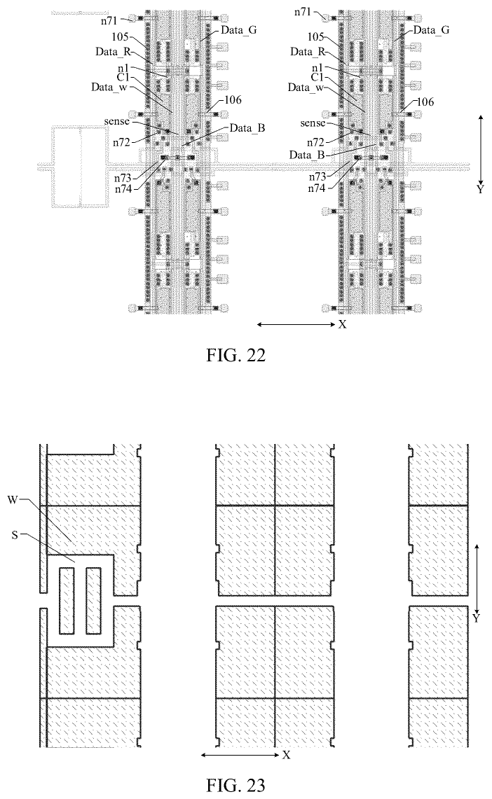

FIG. 21 is a partial schematic diagram of a source and drain layer according to some embodiments of the present disclosure. FIG. 22 is a partial schematic diagram of stack of a light-shielding layer, a semiconductor layer, a gate layer, an interlayer dielectric layer, and a source and drain layer according to some embodiments of the present disclosure. Referring to FIG. 21 and FIG. 22, the source and drain layer n7 includes the first power line 105, the third data signal line (Data_w), the first data signal line (Data_R), the sensing signal line (sense), the second data signal line (Data_B), the fourth data signal line (Data_G), the auxiliary electrode line 106, the first capacitor plate C1 in the storage capacitor C, a first source and drain portion n71, a second source and drain portion n72, a third source and drain portion n73, and a fourth source and drain portion n74.

The first capacitor plate C1 in the source and drain layer n7 is connected to the first capacitor plate C1 in the light-shielding layer n1 through the via 2. The first source and drain portion n71 is configured to connect the capacitor connection portion n1-2 in the light-shielding layer n1 to the anode layer n10, the second source and drain portion n72 is configured to connect the second electrode of the second transistor T2 to the second capacitor plate C2 in the gate layer n5 to form the second node J2 shown in FIG. 11, the third source and drain portion n73 is configured to connect the second gate signal line 103a2 and the gate electrode of the second transistor T2, and the fourth source and drain portion n74 is configured to connect the sensing signal line sense to the first electrode of the second transistor T2.

In the embodiments of the present disclosure, a passivation film layer is formed upon formation of the source and drain layer n7. The passivation film layer is configured to form the passivation layer n8, and the passivation layer n8 is made of an inorganic material, for example, silicon nitride. The passivation film layer is a whole-layer film layer, and the passivation layer n8 includes a plurality of vias n81.

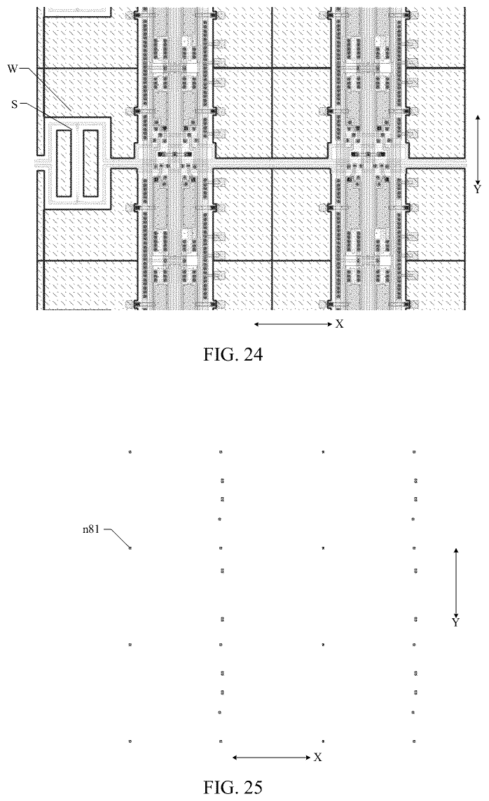

FIG. 23 is a partial schematic diagram of a planarization layer according to some embodiments of the present disclosure. FIG. 24 is a partial schematic diagram of stack of a light-shielding layer, a semiconductor layer, a gate layer, an interlayer dielectric layer, a source and drain layer, and a planarization layer according to some embodiments of the present disclosure. Referring to FIG. 23 and FIG. 24, the planarization layer n9 includes a material region S and a void region W. The material region S is disposed in the plurality of pixel light-emitting regions 101al, and covers the plurality of gate signal lines 103 and the protection pattern 104. The void region W is disposed in the transparent region 101a2, the regions of the plurality of gate signal lines 103, and the region of the protection pattern 104.

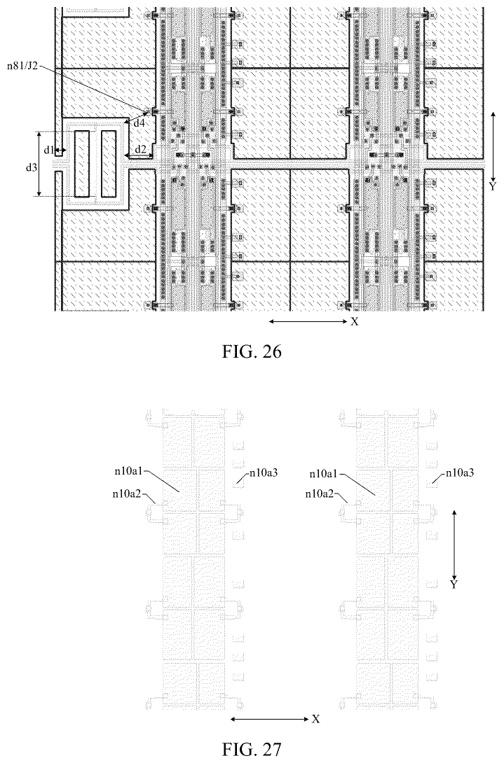

Upon formation of the planarization layer n9, the passivation film layer is processed to acquire the plurality of vias n81 shown in FIG. 25 and FIG. 26 to form the passivation layer n8.

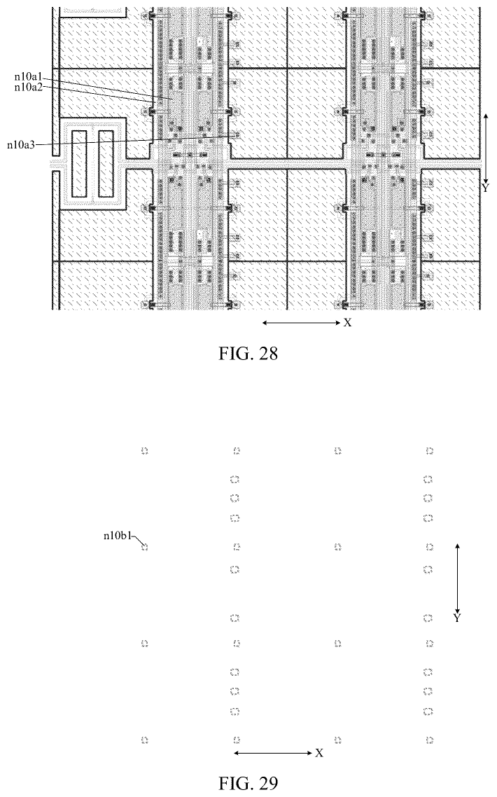

FIG. 27 is a partial schematic diagram of a first anode film layer in an anode layer according to some embodiments of the present disclosure. FIG. 28 is a partial schematic diagram of stack of a light-shielding layer, a semiconductor layer, a gate layer, an interlayer dielectric layer, a source and drain layer, a passivation layer, a planarization layer, and a first anode film layer according to some embodiments of the present disclosure. Referring to FIG. 27 and FIG. 28, the first anode film layer includes a first anode pattern n10a1, a second anode pattern n10a2, and a third anode pattern n10a3. It should be noted that the second node J2 may be the lapping point of the second anode pattern n10a2 and the via n81 in the passivation layer n8.

The region of each sub-pixel 1021 has two first anode patterns n10a1, and the two first anode patterns n10a1 are connected to each other through the second anode pattern n10a2. In some embodiments, the region of each sub-pixel 1021 has one first anode pattern n10a1, and the second anode pattern n10a2 is not required in this case. The third anode pattern n10a3 is configured to connect the auxiliary electrode line 106 to the subsequently formed cathode layer n13. The first anode film layer n10a is made of ITO.

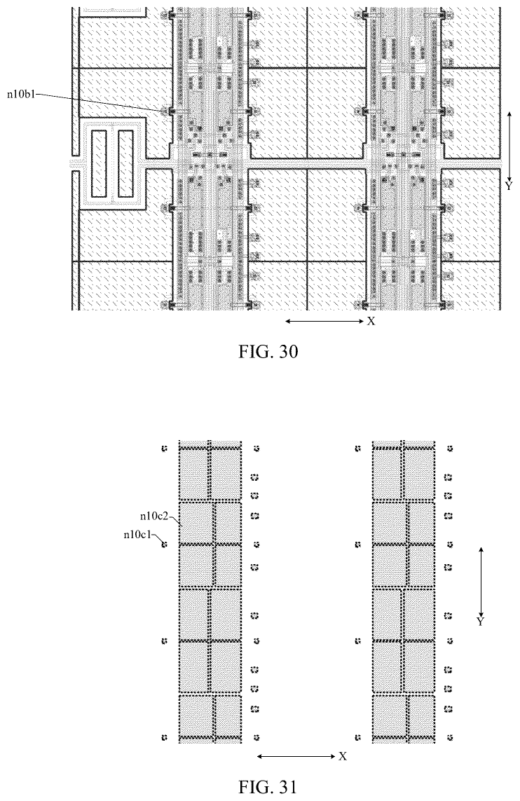

FIG. 29 is a partial schematic diagram of a second anode film layer in an anode layer according to some embodiments of the present disclosure. FIG. 30 is a partial schematic diagram of stack of a light-shielding layer, a semiconductor layer, a gate layer, an interlayer dielectric layer, a source and drain layer, a passivation layer, a planarization layer, a first anode film layer, and a second anode film layer according to some embodiments of the present disclosure. Referring to FIG. 30 and FIG. 29, the second anode film layer includes a fourth anode pattern n10b1. The fourth anode pattern n10b1 is configured to connect the first anode film layer n10a and the third anode film layer n10c. The second anode film layer n10b is made of ITO.

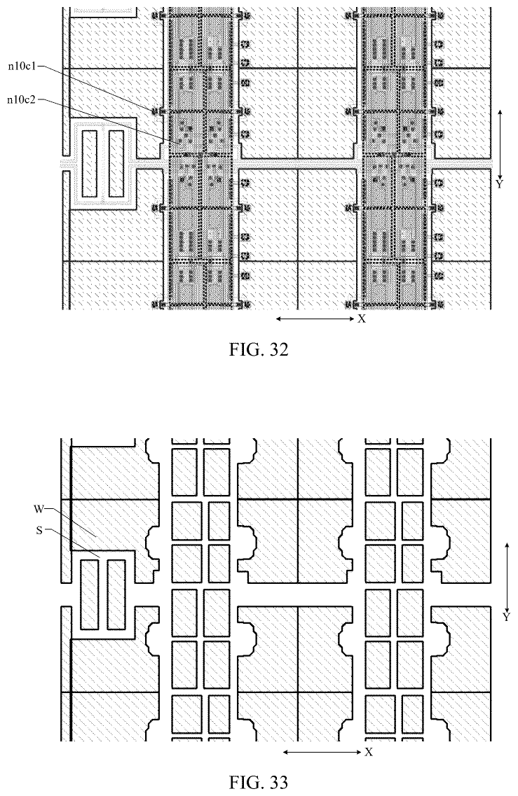

FIG. 31 is a partial schematic diagram of a third anode film layer in an anode layer according to some embodiments of the present disclosure. FIG. 32 is a partial schematic diagram of stack of a light-shielding layer, a semiconductor layer, a gate layer, an interlayer dielectric layer, a source and drain layer, a passivation layer, a planarization layer, a first anode film layer, a second anode film layer, and a third anode film layer according to some embodiments of the present disclosure. Referring to FIG. 31 and FIG. 32, the third anode film layer n10c includes a fifth anode pattern n10c1 and a sixth anode pattern n10c2. The fifth anode pattern n10c1 is configured to be connected to the second anode pattern n10a2, and the sixth anode pattern n10c2 acts as a reflection node of the sub-pixel and made of ITO and Cu.

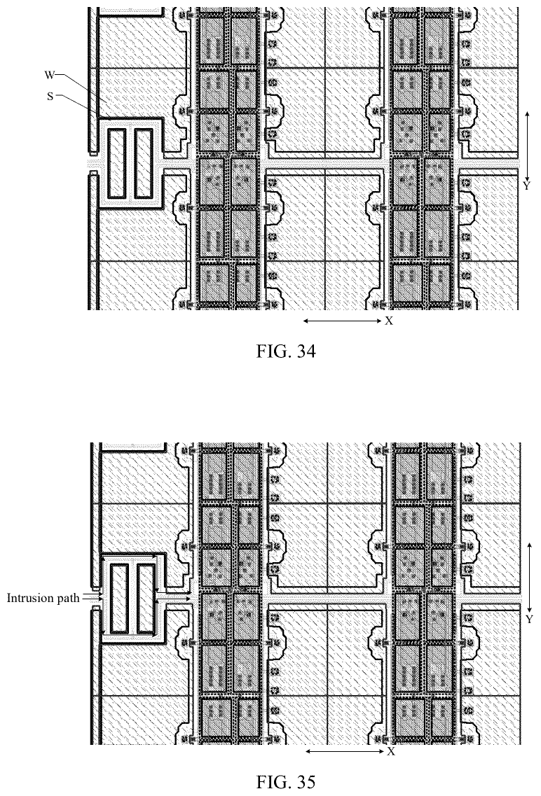

FIG. 33 is a partial schematic diagram of a pixel define layer according to some embodiments of the present disclosure. FIG. 34 is a partial schematic diagram of stack of a light-shielding layer, a semiconductor layer, a gate layer, an interlayer dielectric layer, a source and drain layer, a passivation layer, a planarization layer, a first anode film layer, a second anode film layer, a third anode film layer, and a pixel define layer according to some embodiments of the present disclosure. Referring to FIG. 33 and FIG. 34, the pixel define layer n11 includes a material region S and a void region W. The material region S is disposed in the plurality of pixel light-emitting regions 101a1, and covers the plurality of gate signal lines 103 and the protection pattern 104. The void region W is disposed in the transparent region 101a2, the regions of the plurality of gate signal lines 103, and the region of the protection pattern 104.

In addition, the void region W is further disposed in the pixel light-emitting region 101a1, and the void region W disposed in the pixel light-emitting region 101a1 is configured to expose the sixth anode pattern n10c of the third anode film layer n10, such that the subsequently formed light-emitting layer is in contact with the sixth anode pattern n10c, and the area of the light-emitting region is increased.

FIG. 35 is a schematic diagram of an intrusion path of moisture or oxygen according to some embodiments of the present disclosure. It can be seen referring to FIG. 35 that the moisture or oxygen intrudes the pixel unit 102 upon passing through the bent portion of the gate signal line 103, such that the intrusion path is long, the reliability of the product is enhanced, and technical support for mass production is provided.

It should be noted that the display panel 100 further includes the gate drive circuit, or referred to as a gate driven on array (GOA), in the periphery region. The gate drive circuit is connected to the first section 1031 of the gate signal line 103 to supply the gate drive signal to the gate signal line 103. Illustratively, the gate drive circuits are disposed on left and right sides in the periphery region.

In summary, the embodiments of the present disclosure provide a display panel. The display panel includes the base substrate, the plurality of pixel units, and the plurality of gate signal lines. The gate signal line includes the body portion extending in the first direction and the bent portion connected to the body portion and disposed in the target transparent region in the display region of the base substrate close to the periphery region. As the path length of the bent portion is long, the intrusion path of the moisture or oxygen into the pixel unit is long, and the possibility of the moisture or oxygen entering the pixel unit is efficiently reduced, such that the yield of the display panel is improved, and the display effect of the display panel is ensured.

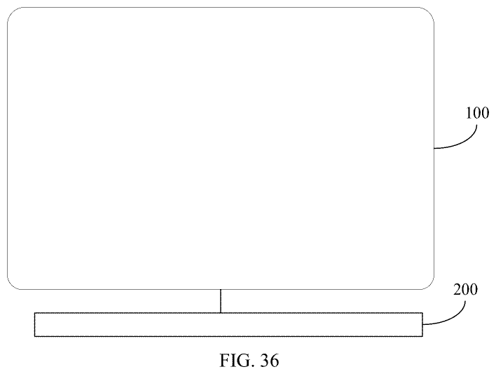

FIG. 36 is a schematic structural diagram of a display device according to some embodiments of the present disclosure. As shown in FIG. 36, the display device includes a power supply assembly 200 and the display panel 100 in the above embodiments. The power supply assembly 200 is configured to supply power to the display panel 100.

In some embodiments, the display panel is an organic light-emitting diode (OLED) display panel, and thus the display device is an OLED display device. Illustratively, the display panel is an active-matrix organic light-emitting diode (AMOLED) display panel, and thus the display device is an AMOLED display device.

In some embodiments, the display device is any suitable display device, including but not limited to a mobile phone, a tablet, a television, a monitor, a laptop computer, a digital photo frame, a navigators, an e-books, and any other products or assemblies with the display function.

In addition, the display device is applicable to a fanout in AA (FIP) technology or a VSS in AA (SIP) technology.

The display device has basically the same technical effects as the display panel in above embodiments, and thus the technical effects of the display device are not repeated herein for conciseness.

The terms used in the embodiments of the present disclosure are only used to explain the embodiments of the present disclosure, and are not intended to limit the present disclosure. Unless otherwise defined, technical or scientific terms used in the present disclosure shall have ordinary meaning understood by persons of ordinary skill in the art to which the disclosure belongs.

The terms “first,” “second,” “third,” and the like in the description and claims of the present disclosure are not intended to indicate or imply any sequence, number or importance, and are only used to distinguish different portions. Similarly, the terms “a,” “an,” and the like are not intended to limit the quantity, and only represent that at least one exists. The terms “include” or “comprise” and the like are used to indicate that the element or object preceding the terms covers the element or object following the terms and its equivalents, and shall not be understood as excluding other elements or objects. The terms “connection,” “contact,” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly. The terms “connection” and “coupling” refer to electrical connection.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

What is claimed is:

1. A display panel, comprising:
a base substrate, having a display region and a periphery region surrounding the display region, wherein the display region comprises a plurality of pixel light-emitting regions and a plurality of transparent regions, the plurality of transparent regions comprising at least one target transparent region arranged in a first direction;
a plurality of pixel units, disposed on the base substrate and in the plurality of pixel light-emitting regions; and
a plurality of gate signal lines, arranged in a second direction, wherein the second direction is intersected with the first direction, and each of the plurality of gate signal lines comprises a first section in the periphery region and a second section in the display region, wherein the second section comprises a body portion extending in the first direction and a bent portion connected to the body portion, the bent portion being disposed in the at least one target transparent region, and a path length of the bent portion being greater than a length of the at least one target transparent region in the first direction.

2. The display panel according to claim 1, further comprising: a protection pattern and a first insulation layer between the protection pattern and the plurality of gate signal lines, wherein the protection pattern is disposed in the at least one target transparent region, an orthographic projection of the bent portion on the base substrate is on a side of an orthographic projection of the protection pattern on the base substrate, and the orthographic projection of the protection pattern on the base substrate is partially overlapped with the orthographic projection of the bent portion on the base substrate.

3. The display panel according to claim 2, wherein the bent portion comprises a first bent portion, a second bent portion, and a third bent portion that are connected in sequence, and the plurality of gate signal lines form a plurality of signal line groups, each group of the plurality of signal line groups comprising two adjacent gate signal lines; wherein
the first bent portion in each of the two adjacent gate signal lines is disposed in a side, away from the periphery region, of the protection pattern, and the third bent portion in each of the two adjacent gate signal lines is disposed in a side, close to the periphery region, of the protection pattern; and
an orthographic projection of the second bent portion of a first gate signal line in the two adjacent gate signal lines on the base substrate is on a first side of the orthographic projection of the protection pattern on the base substrate and is partially overlapped with the orthographic projection of the protection pattern on the base substrate, and an orthographic projection of the second bent portion of a second gate signal line in the two adjacent gate signal lines on the base substrate is on a second side of the orthographic projection of the protection pattern on the base substrate and is partially overlapped with the orthographic projection of the protection pattern on the base substrate, wherein the first side and the second side are two sides, arranged in the second direction, of the orthographic projection of the protection pattern on the base substrate.

4. The display panel according to claim 3, wherein orthographic projections of bent portions of the two gate signal lines on the base substrate surround the orthographic projection of the protection pattern on the base substrate.

5. The display panel according to claim 4, wherein the bent portions of the two gate signal lines define a first annular region, a portion of the first gate signal line in one of the plurality of pixel light-emitting regions has a second annular region, and a portion of the second gate signal line in one of the plurality of pixel light-emitting regions has a third annular region;
wherein an area of the first annular region is greater than an area of the second annular region and an area of the third annular region.

6. The display panel according to claim 5, wherein the at least one target transparent region comprises a first target transparent region, wherein the first target transparent region is closer to the periphery region than the plurality of pixel light-emitting regions;
wherein for the first annular region defined by the bent portions of the two gate signal lines in the first target transparent region, a distance between the first annular region and one of the plurality of pixel light-emitting regions is greater than a distance between the first annular region and the periphery region.

7. The display panel according to claim 6, wherein the protection pattern is a stripe pattern extending in the second direction, and a length of the protection pattern in the second direction is greater than the distance between the first annular region in the first target transparent region and one of the plurality of pixel light-emitting regions.

8. The display panel according to claim 6, wherein the at least one target transparent region further comprises a second target transparent region, wherein the second target transparent region is disposed between two adjacent pixel light-emitting regions in the plurality of pixel light-emitting regions;
wherein for the first annular region defined by the bent portions of the two gate signal lines in the second target transparent region, distances between the second annular region and the two adjacent pixel light-emitting regions are equal.

9. The display panel according to claim 3, wherein
a first protrusion is arranged on a side, close to the protection pattern, of the second bent portion of the first gate signal line, wherein an orthographic projection of a first end portion of the protection pattern on the base substrate is overlapped with an orthographic projection of the first protrusion on the base substrate; and
a second protrusion is arranged on a side, close to the protection pattern, of the second bent portion of the second gate signal line, wherein an orthographic projection of a second end portion of the protection pattern on the base substrate is overlapped with an orthographic projection of the second protrusion on the base substrate.

10. The display panel according to claim 9, comprising: a pixel unit layer, wherein the pixel unit layer comprises the plurality of pixel units and a semiconductor layer between the base substrate and the first insulation layer, wherein the protection pattern is disposed in the semiconductor layer, and each of the first end portion and the second end portion of the protection pattern is made of a semiconductor material.

11. The display panel according to claim 2, comprising: a pixel unit layer, wherein the pixel unit layer comprises the plurality of pixel units, and a gate layer, a second insulation layer, and a cathode layer that are stacked in a direction away from the base substrate in sequence;
wherein the plurality of gate signal lines are disposed in the gate layer, an orthographic projection of the second insulation layer on the base substrate covers orthographic projections of the plurality of gate signal lines on the base substrate and the orthographic projection of the protection pattern on the base substrate.

12. The display panel according to claim 11, wherein
the second insulation layer comprises a material region containing an insulative material and a void region without any insulative material; wherein
the material region is disposed in the plurality of pixel light-emitting regions, and an orthographic projection of the material region on the base substrate covers the orthographic projection of the protection pattern on the base substrate and the orthographic projections of the plurality of gate signal lines on the base substrate; and
the void region is disposed on a side, away from the orthographic projection of the protection pattern on the base substrate, of the orthographic projections of the plurality of gate signal lines on the base substrate, disposed between the orthographic projections of the plurality of gate signal lines on the base substrate and the orthographic projection of the protection pattern on the base substrate, and disposed in other regions of the plurality of transparent regions than regions of the orthographic projections of the plurality of gate signal lines on the base substrate; or
the second insulation layer at least comprises a first insulation sub-layer and a second insulation sub-layer that are stacked in the direction away from the base substrate in sequence, wherein a boundary of an orthographic projection of the first insulation sub-layer on the base substrate is not overlapped with a boundary of an orthographic projection of the second insulation sub-layer on the base substrate.

13. (canceled)

14. The display panel according to claim 1, wherein
each of the plurality of pixel light-emitting regions and the plurality of transparent regions is a stripe region extending in the second direction, the plurality of pixel light-emitting regions and the plurality of transparent regions are staggered in the first direction, the plurality of transparent regions comprise two target transparent regions, and the plurality of pixel light-emitting regions and other transparent regions in the plurality of transparent regions than the two target transparent regions are disposed between the two target transparent regions; and
each of the plurality of gate signal lines comprises two bent portions, wherein one bent portion in the two bent portions is connected to an end of the body portion and is disposed in one target transparent region in the two target transparent regions, and another bent portion in the two bent portions is connected to another end of the body portion and is disposed in another target transparent region in the two target transparent regions.

15. The display panel according to claim 1, wherein the plurality of pixel units are arranged in an array and comprise a plurality of first pixel unit groups arranged in the second direction, wherein each group of the plurality of first pixel unit groups comprises multiple pixel units arranged in the first direction, each of the plurality of gate signal lines is connected to the multiple pixel units in one group of the plurality of first pixel unit groups, and the multiple pixel units in the each group of the plurality of first pixel unit groups are connected to two gate signal lines in one group of a plurality of signal line groups formed by the plurality of gate signal lines.

16. The display panel according to claim 15, wherein each of the plurality of pixel units comprise a first group of sub-pixels and a second group of sub-pixels that are arranged in the second direction, wherein the first group of sub-pixels comprises at least one sub-pixel, the second group of sub-pixels comprises at least one sub-pixel, and body portions of the two gate signal lines connected to the multiple pixel units in the each group of the plurality of first pixel unit groups are disposed between the first group of sub-pixels and the second group of sub-pixels.

17. The display panel according to claim 16, wherein the body portion comprises a first primary path line and a plurality of first secondary path lines; wherein
two ends of each of the plurality of first secondary path lines are connected to the first primary path line, the first primary path line is connected to the at least one sub-pixel in first groups of sub-pixels of the multiple pixel units in one group of the plurality of first pixel unit groups, and each of the plurality of first secondary path lines is connected to the at least one sub-pixel in the second group of sub-pixels of one of the multiple pixel units.

18. The display panel according to claim 17, wherein
the plurality of pixel units comprise a plurality of second pixel unit groups arranged in the first direction, wherein each of the plurality of second pixel unit groups comprises multiple pixel units arranged in the second direction;
the display panel further comprises a plurality of first power lines corresponding to the plurality of second pixel unit groups, and a plurality of corresponding auxiliary electrode lines, wherein each of the plurality of first power lines comprises a primary power line and a plurality of branch power lines, the plurality of branch power lines being connected to the primary power line, and the primary power line being disposed on a side of a corresponding second pixel unit group; each of the plurality of first power lines is connected to sub-pixels in the multiple pixel units in one group of the plurality of second pixel unit groups, and each of the plurality of auxiliary electrode lines is disposed on another side of the corresponding second pixel unit group and is connected to a cathode layer in the multiple pixel units; and
for the primary power line and one of the plurality of auxiliary electrode lines of one of the plurality of first power lines corresponding to one group of the plurality of second pixel unit groups, one of connection positions between the two ends of one of the plurality of first secondary path lines and the first primary path line is disposed on a side, away from the one of the plurality of auxiliary electrode lines, of the primary power line, and another of the connection positions between the two ends of one of the plurality of first secondary path lines and the first primary path line is disposed on a side, away from the primary power line, of the one of the plurality of auxiliary electrode lines.

19. The display panel according to claim 17, wherein
the plurality of pixel units comprise a plurality of second pixel unit groups arranged in the first direction, wherein each group of the plurality of second pixel unit groups comprises multiple pixel units arranged in the second direction;
the display panel further comprises a plurality of first power lines corresponding to the plurality of second pixel unit groups, and a plurality of corresponding auxiliary electrode lines, wherein each of the plurality of first power lines comprises a primary power line and a plurality of branch power lines, the plurality of branch power lines being connected to the primary power line, and the primary power line being disposed on a side of a corresponding second pixel unit group; each of the plurality of first power lines is connected to the multiple pixel units in one group of the plurality of second pixel unit groups, and each of the plurality of auxiliary electrode lines is disposed on another side of the corresponding second pixel unit group and is connected to a cathode layer in the multiple pixel units;
for the primary power line and one of the plurality of auxiliary electrode lines of one of the plurality of first power lines corresponding to one group of the plurality of second pixel unit groups, two connection positions between the two ends of one of the plurality of first secondary path lines and the first primary path line are disposed between the primary power line and the one of the plurality of auxiliary electrode lines; and
the body portion further comprises a plurality of second secondary path lines and a plurality of third secondary path lines, wherein two ends of each of the plurality of second secondary path lines are connected to the first primary path line, and two connection positions between the two ends of each of the plurality of second secondary path lines and the first primary path line are disposed on two side of the primary power line; and two ends of each of the plurality of third secondary path lines are connected to the first primary path line, and two connection positions between the two ends of each of the plurality of third secondary path lines and the first primary path line are disposed on two side of the one of the plurality of auxiliary electrode lines.

20. The display panel according to claim 18, wherein
the first group of sub-pixels comprises a first sub-pixel and a second sub-pixel, and the second group of sub-pixels comprises a third sub-pixel and a fourth sub-pixel; and the display panel further comprises a plurality of data signal line groups corresponding to the plurality of second pixel unit groups, wherein each group of the plurality of data signal line groups comprises a plurality of data signal lines arranged in the first direction, a target data signal line in the plurality of data signal lines being disposed between the first sub-pixel and the second sub-pixel and between the third sub-pixel and the fourth sub-pixel, and being at least one data signal line in the plurality of data signal lines; and
each of the plurality of branch power lines comprises a second primary path line and a fourth secondary path line, wherein two ends of the fourth secondary path line are connected to the second primary path line, and two connection positions between the two ends of the fourth secondary path line and the second primary path line are disposed on two sides of the target data signal line.

21. (canceled)

22. (canceled)

23. (canceled)

24. (canceled)

25. A display device, comprising: a power supply assembly, and a display panel; wherein
the display panel comprises:
a base substrate, having a display region and a periphery region surrounding the display region, wherein the display region comprises a plurality of pixel light-emitting regions and a plurality of transparent regions, the plurality of transparent regions comprising at least one target transparent region arranged in a first direction;
a plurality of pixel units, disposed on the base substrate and in the plurality of pixel light-emitting regions; and
a plurality of gate signal lines, arranged in a second direction, wherein the second direction is intersected with the first direction, and each of the plurality of gate signal lines comprises a first section in the periphery region and a second section in the display region, wherein the second section comprises a body portion extending in the first direction and a bent portion connected to the body portion, the bent portion being disposed in the at least one target transparent region, and a path length of the bent portion being greater than a length of the at least one target transparent region in the first direction; and
the power supply assembly is connected to the display panel and is configured to supply power to the display panel.
